(19) United States
(12) Patent Application Publication
(10) Pub. No.: US 2026/0314219 A1
(43) Pub. Date: Oct. 8, 2026

(54) MULTI GAMUT DISPLAYS

(71) Applicant: Excyton Limited, Sedgefield, Durham (GB)

(72) Inventor: Peter LEVERMORE, Burringham, North Lincolnshire (GB)

(21) Appl. No.: 19/481,484

(22) PCT Filed: May 13, 2024
(86) PCT No.: PCT/GB2024/051239

§ 371 Date: Nov. 4, 2025

(30) Foreign Application Priority Data
May 13, 2023 (GB) 2307151.7

(51) Int. Cl. H10K 59/35

(52) U.S. Cl. CPC H10K 59/352; H10K 59/353

(57) ABSTRACT

A display is provided. In one embodiment, the display comprises an arrangement of pixels, each pixel comprising: a first region configured to emit red light of a first chromaticity having first CIE 1931 (x, y) chromaticity coordinates of (x1, y1); a second region configured to emit red light of a second chromaticity having second CIE 1931 (x, y) chromaticity coordinates of (x2, y2); a third region configured to emit green light of a third chromaticity having third CIE 1931 (x, y) chromaticity coordinates of (x3, y3); a fourth region configured to emit green light of a fourth chromaticity having fourth CIE 1931 (x, y) chromaticity coordinates of (x4, y4); a fifth region configured to emit blue light of a fifth chromaticity having fifth CIE 1931 (x, y) chromaticity coordinates of (x5, y5); and a sixth region configured to emit blue light of a sixth chromaticity having sixth CIE 1931 (x, y) chromaticity coordinates of (x6, y6); wherein the second chromaticity is different to the first chromaticity; the fourth chromaticity is different to the third chromaticity; and the sixth chromaticity is different to the fifth chromaticity; wherein the first, third and fifth chromaticities define the primary colours of a first colour gamut; the second, fourth and sixth chromaticities define the primary colours of a second colour gamut; the area of the first colour gamut is less than 55% of the area of the second colour gamut in the CIE 1931 (x, y) chromaticity diagram; the first colour gamut and the second colour gamut both enclose the D65 white point; and the fifth region emits blue light with CIE 1931 x coordinate x5 in the range of 0.075 to 0.155 and CIE 1931 y coordinate y5 in the range of 0.081 to 0.245.

### TECHNICAL FIELD

The present invention relates to multi-primary colour displays, and in particular to multi-primary displays comprising regions that emit light of the same hue but different chromaticity.

### BACKGROUND

Display technology is advancing rapidly, with recent innovations enabling thinner and lighter displays with higher resolution, improved frame rate and enhanced contrast ratio. However, one area where significant improvement is still required is colour gamut. Displays of today are currently incapable of producing many of the colours the average person experiences in day-to-day life.

To unify and guide the industry towards improved colour gamut, two industry standards have been defined, DCI-P3 and Rec. 2020, with DCI-P3 often seen as a steppingstone towards Rec. 2020. DCI-P3 was defined by the Digital Cinema Initiatives (DCI) organization and published by the Society of Motion Picture and Television Engineers (SMPTE). Rec. 2020 (more formally known as ITU-R Recommendation BT. 2020) was developed by the International Telecommunication Union to set targets, including an improved colour gamut, for various aspects of ultra-high-definition televisions.

As depicted in Table 1, displays such as commercial organic light emitting diode (OLED) displays incorporating organic light emitting material can successfully render the DCI-P3 colour gamut. For example, state-of-the-art smartphones with OLED displays such as the iPhone 14 Pro Max or Samsung Galaxy S22 can render the DCI-P3 gamut. Displays incorporating other light emitting diodes (LEDs) such as quantum dot light emitting diodes (QLEDs), perovskite light emitting diodes (PeLEDs) and Inorganic LEDs (I-LEDs) also have the potential to render the DCI-P3 colour gamut.

Rec. 2020 is a more challenging standard than DCI-P3. Until now, no display has been commercialized that can render the Rec. 2020 colour gamut. This can be explained with reference to the CIE 1931 (x, y) chromaticity diagram which was created by the Commission Internationale de l′Éclairage (CIE) in 1931 to define all colour sensations that an average person can experience. Mathematical relationships describe the location of each colour within the chromaticity diagram. The CIE 1931 (x, y) chromaticity diagram may be used to quantify the colour gamut of displays. The white point (D65) is at the centre, while colours become increasingly saturated towards the extremities of the diagram. FIG. 3 shows the CIE 1931 (x, y) chromaticity diagram with labels added to different locations on the diagram to enable a general understanding of distribution of colour within the colour space. FIG. 4 shows (a) DCI-P3 and (b) Rec. 2020 colour spaces superimposed on the CIE 1931 (x, y) chromaticity diagram. The tips of the triangles are primary colours for DCI-P3 and Rec. 2020, respectively, while colours enclosed within the triangles are all the colours that can be reproduced by combining these primary colours. For a display to meet DCI-P3 colour gamut specifications, the red, green and blue sub-pixels of the display must emit light at least as deep in colour as the DCI-P3 primary colours. For a display to meet Rec. 2020 colour gamut specifications, the red, green and blue sub-pixels of the display must emit light at least as deep in colour as the Rec. 2020 primary colours. Primary colours for Rec. 2020 are significantly deeper than for DCI-P3, and therefore achievement of the Rec. 2020 standard for colour gamut is a greater technical challenge than achievement of the DCI-P3 standard.

One further challenge is that state-of-the-art displays suffer a trade-off whereby efficiency and/or lifetime are typically reduced as the colour gamut of the display is extended. This trade-off arises because as red, green and blue light emitted from the sub-pixels of the display become deeper in colour, there is less overlap of the respective red, green and blue emission spectra with the photopic luminous efficiency function which describes the average spectral sensitivity of human visual perception of brightness under everyday lighting. The red, green and blue sub-pixels that are deeper in colour therefore appear less bright.

To illustrate this challenge, the normalized CIE 1931 photopic luminous efficiency function is depicted in FIG. 5 across a wavelength range of 380 nm to 780 nm. Light is perceived to be brightest at approximately 555 nm to 557 nm, with perception of brightness falling off gradually towards zero at 380 nm and 780 nm. Also plotted on FIG. 5 are exemplary normalized emission spectra for light-red, deep-red, light-green, deep-green, light-blue and deep-blue OLEDs, with respective emission spectra peaks labelled at 606 nm, 642 nm, 545 nm, 521 nm, 472 nm and 451 nm. The emission spectra for deep-red, deep-green and deep-blue OLEDs have less overlap with the photopic luminous efficiency function than the respective light-red, light-green and light-blue OLEDs of the same hue. This same principle also applies to other LEDs such as QLEDs, PeLEDs and I-LEDs.

FIG. 4 demonstrates that for a display such as an OLED display to render a more extensive colour gamut, the red sub-pixel must emit light closer in peak wavelength to the end of the spectral locus at 780 nm, the green sub-pixel must emit light with a peak wavelength in the range of approximately 515 nm to 540 nm, and the blue sub-pixel must emit light closer in peak wavelength to the end of the spectral locus at 380 nm. However, as depicted in FIG. 5, human visual perception of brightness decreases for red towards 780 nm, decreases for blue towards 380 nm, and is substantially less in the range of 515 nm to 540 nm than at the peak of the photopic luminous efficiency function at approximately 555 nm to 557 nm. This is the reason for the trade-off between colour gamut and efficiency and/or lifetime in the displays of today.

One further challenge is that state-of-the-art displays suffer poor performance under bright ambient light, such as sunlight, where the bright ambient light reflects off the surface of the display towards the user and washes out light emitted by the display. This image then appears relatively dim to the user with unsaturated colours. This effect can be reduced by increasing the brightness of the display, but this then results in increased display power consumption and reduced battery life of the consumer product that incorporates the display, which is inconvenient to the user and damaging to the environment.

The present invention relates to multi-primary colour displays, and in particular to multi-primary displays comprising regions that emit light of the same hue but different chromaticity.

The present invention addresses the challenges described herein by providing a means to enhance the colourfulness and brightness of displays and/or reducing their power consumption. The regions that emit light of the same hue but different chromaticity may emit red, green or blue light. The display may comprise regions that emit deeper red, green or blue light, and regions that emit lighter red, green or blue light.

When the display image requires relatively unsaturated red, green or blue light, the regions that emit lighter red, green or blue light may emit light to generate the display image while the regions that emit deeper red, green or blue light may remain inactive. However, when the display image requires relatively saturated red, green or blue light, the regions that emit deeper red, green or blue light may emit light to generate the display image. Light may be emitted from the relatively more efficient lighter red, green or blue regions to render most display images, while light emitted from the relatively less efficient deeper red, green or blue regions may only be required to render a small proportion of images. The power consumption of the display may therefore be reduced, and the battery life of a consumer product incorporating the display may be extended.

Some or all the savings in display power consumption can optionally be reinvested in increasing the brightness of the display. This may be especially beneficial in improving sunlight readability.

Some or all the savings in display power consumption can optionally be reinvested in extending the colour gamut of the display. This is because the light emitted from the relatively less efficient deeper red, green or blue regions may only be required to render a small proportion of images, so the increase in display power consumption arising from decreased overlap with the photopic luminous efficiency function is minimized. This may enable the display to render a wider colour gamut without increasing power consumption relative to a standard display (such as the OLED display in the iPhone 14 Pro Max or Samsung Galaxy S22) having single red, green and blue sub-pixels. Optionally, the regions that emit deeper red, green and blue light may be configured to emit light at the primary colours of the DCI-P3 colour gamut. This may enable the display to render the DCI-P3 colour gamut. Optionally, the regions that emit deeper red, green and blue light may be configured to render a wider colour gamut than the DCI-P3 colour gamut.

Optionally, the regions that emit deeper red, green and blue light may be configured to emit light at the primary colours of the Rec. 2020 colour gamut. This may enable the display to render the Rec. 2020 colour gamut.

The proposed display design is ideally suited to OLED devices and displays. It can also be incorporated into displays comprising QLEDs, PeLEDs or I-LEDs. It can also be incorporated into displays comprising MiniLEDs, MicroLEDs or NanoLEDs that comprise OLEDs, I-LEDs, QLEDs or PeLEDs.

Inherent properties of organic light emitting materials, quantum dot light emitting materials and perovskite light emitting materials render them well-suited to the herein disclosed display architecture. These properties include optical band gaps that are readily tunable across the visible, ultra-violet and infra-red spectra, high colour saturation that enables displays with wide colour gamut, excellent charge transport properties and low non-radiative rates. As an overview, several OLED materials and configurations are described in Uoyama et al. and in European patent EP 0423283 B1 and United States patents U.S. Pat. No. 6,303,238 B1 and U.S. Pat. No. 7,279,704 B2. Several QLED materials and configurations are described in Kathirgamanathan et al. Several PeLED materials and configurations are described in Adjokatse et al. All these references are included herein by reference in their entirety.

As used herein, the term “organic” includes polymeric materials as well as small molecule organic materials that may be used to fabricate optoelectronic devices, such as OLEDs. As used herein, the term small molecule refers to any organic material that is not a polymer, and small molecules may be quite large. Small molecules may include repeat units in some circumstances. For example, using a long chain alkyl group as a substituent does not remove a molecule from the small molecule class. Small molecules may also be incorporated into polymers, for example as a pendant group on a polymer backbone or as part of the backbone. A dendrimer may be a small molecule and it is believed that all dendrimers currently used in the field of OLEDs are small molecules.

As used herein the term “organic light emitting material” includes fluorescent and phosphorescent organic light emitting materials, as well as organic materials that emit light through mechanisms such as triplet-triplet annihilation (TTA), thermally activated delayed fluorescence (TADF) or hyperfluorescence. One example of organic light emitting material that emits red light is bis(2-(3,5-dimethylphenyl)quinoline-C2,N′) (acetylacetonato) iridium (III) Ir(dmpq)₂(acac). One example of organic light emitting material that emits green light is tris(2-phenylpyridine) iridium (Ir(ppy)₃). One example of organic light emitting material that emits blue is light bis[2-(4,6-difluorophenyl)pyridinato-C2,N](picolinato)iridium(III) (Flrpic).

In general, OLED devices may be photoluminescent or electroluminescent. The term “OLED” may be used to describe single emissive unit electroluminescent devices that comprise electroluminescent organic light emitting material. The term “OLED” may also be used to describe stacked electroluminescent devices or one or more emissive units of stacked electroluminescent devices that comprise electroluminescent organic light emitting material. This nomenclature may differ slightly from that used by other sources.

As used herein, the term “quantum dot” includes quantum dot material, quantum rod material and other luminescent nanocrystal material, with the exception of “perovskite” material, which is defined separately herein. Quantum dots may generally be considered as semiconductor nanoparticles that exhibit properties that are intermediate between bulk semiconductors and discrete molecules. Quantum dots may comprise III-V semiconductor material, such as gallium nitride (GaN), gallium phosphide (GaP), gallium arsenide (GaAs), indium phosphide (InP) and indium arsenide (InAs), or II-VI semiconductor material, such as zinc oxide (ZnO), zinc sulfide (ZnS), cadmium sulfide (CdS), cadmium selenide (CdSe) and cadmium telluride (CdTe), or combinations thereof. In general, as a result of quantum confinement effects, optoelectronic properties of quantum dots may change as a function of size or shape of the quantum dot.

Several types of quantum dot may be stimulated to emit light in response to optical or electrical excitation. That is to say that quantum dot light emitting material may be photoluminescent or electroluminescent. This nomenclature may differ slightly from that used by other sources.

As used herein, the term “quantum dot” does not include “perovskite” material. Several types of perovskite material, such as perovskite nanocrystals, 2D perovskite materials and Quasi-2D perovskite materials, are semiconducting materials that exhibit properties intermediate between bulk semiconductors and discrete molecules, where in a similar manner to quantum dots, quantum confinement may affect optoelectronic properties. However, as used herein, such materials are referred to as “perovskite” materials and not “quantum dot” materials. A first reason for this nomenclature is that perovskite materials and quantum dot materials, as defined herein, generally comprise different crystal structures. A second reason for this nomenclature is that perovskite materials and quantum dot materials, as defined herein, generally comprise different material types within their structures. A third reason for this nomenclature is that emission from perovskite material is generally independent of the structural size of the perovskite material, whereas emission from quantum dot material is generally dependent on the structural size (e.g. core and shell) of the quantum dot material. This nomenclature may differ slightly from that used by other sources.

In general, quantum dot light emitting materials comprise a core. Optionally, the core may be surrounded by one or more shells. Optionally, the core and one or more shells may be surrounded by a passivation structure. Optionally, the passivation structure may comprise ligands bonded to the one or more shells. The size of the core and shell(s) may influence the optoelectronic properties of quantum dot light emitting material. Generally, as the size of the core and shell(s) is reduced, quantum confinement effects become stronger, and electroluminescent emission may be stimulated at shorter wavelengths. For display applications, the diameter of the core and shell(s) structure is typically in the range of 1-10 nm. Quantum dots that emit blue light are typically the smallest, with core-shell(s) diameter in the approximate range of 1-2.5 nm. Quantum dots that emit green light are typically slightly larger, with core-shell(s) diameter in the approximate range of 2.5-4 nm. Quantum dots that emit red light are typically larger, with core-shell(s) diameter in the approximate range of 5-7 nm. These ranges are provided by way of example and to aid understanding and are not intended to be limiting.

Examples of quantum dot light emitting materials include materials comprising a core of CdSe. CdSe has a bulk bandgap of 1.73 eV, corresponding to emission at 716 nm. However, the emission spectrum of CdSe may be adjusted across the visible spectrum by tailoring the size of the CdSe quantum dot. Quantum dot light emitting materials comprising a CdSe core may further comprise one or more shells, comprising CdS, ZnS or combinations thereof. Quantum dot light emitting materials comprising CdSe may further comprise a passivation structure, which may include ligands bonded to the shell(s). Quantum dot light emitting materials comprising CdSe/CdS or CdSe/ZnS core-shell structures may be tuned to emit red, green or blue light for application in displays and/or light panels.

Examples of quantum dot light emitting materials further include materials comprising a core of InP. InP has a bulk bandgap of 1.35 eV, corresponding to emission at 918 nm. However, the emission spectrum of InP may be adjusted across the visible spectrum by tailoring the size of the InP quantum dot. Quantum dot light emitting materials comprising an InP core may further comprise one or more shells of CdS, ZnS or combinations thereof. Quantum dot light emitting materials comprising InP may further comprise a passivation structure, which may include ligands bonded to the shell(s). Quantum dot light emitting materials comprising InP/CdS or InP/ZnS core-shell structures may be tuned to emit red, green or blue light for application in displays and/or light panels.

In general, QLED devices may be photoluminescent or electroluminescent. The term “QLED” may be used to describe single emissive unit electroluminescent devices that comprise electroluminescent quantum dot light emitting material. The term “QLED” may also be used to describe stacked electroluminescent devices or one or more emissive units of stacked electroluminescent devices that comprise electroluminescent quantum dot light emitting material. This nomenclature may differ slightly from that used by other sources.

As used herein, the term “perovskite” includes any perovskite material that may be used in an optoelectronic device. Any material that may adopt a three-dimensional (3D) structure of ABX₃, where A and B are cations and X is an anion, may be considered a perovskite material. The A cations may be larger than the B cations. The B cations may be in 6-fold coordination with surrounding X anions. The A anions may be in 12-fold coordination with surrounding X anions.

Perovskite materials are becoming increasingly attractive for application in optoelectronic devices. Many of the perovskite materials used to make such devices are earth-abundant and relatively inexpensive, so perovskite optoelectronic devices have the potential for cost advantages. There are many classes of perovskite material. One class of perovskite material that has shown promise for optoelectronic devices is the metal halide perovskite material class. For metal halide perovskite material, the A component may be a monovalent organic cation, such as methylammonium (CH₃NH₃⁺) or formamidinium (CH(NH₂)₂⁺), an inorganic atomic cation, such as caesium (Cs⁺), or a combination thereof, the B component may be a divalent metal cation, such as lead (Pb⁺), tin (Sn⁺), copper (Cu⁺), europium (Eu⁺) or a combination thereof, and the X component may be a halide anion, such as I⁻, Br⁻, Cl⁻, or a combination thereof. Where the A component is an organic cation, the perovskite material may be defined as an organic metal halide perovskite material. CH₃NH₃PbBr₃ and CH(NH₂)₂PbI₃ are non-limiting examples of metal halide perovskite materials with a 3D structure. Where the A component is an inorganic cation, the perovskite material may be defined as an inorganic metal halide perovskite material. CsPbI₃, CsPbCl₃ and CsPbBr₃ are non-limiting examples of inorganic metal halide perovskite materials.

As used herein, the term “perovskite” further includes any material that may adopt a layered structure of L₂(ABX₃)ₙ₋₁BX₄ (which may also be written as L₂Aₙ₋₁BₙX₃ₙ₊₁), where L, A and B are cations, X is an anion, and n is the number of BX₄ monolayers disposed between two layers of cation L. For metal halide perovskite material, the A component may be a monovalent organic cation, such as methylammonium (CH₃NH₃⁺) or formamidinium (CH(NH₂)₂⁺), an atomic cation, such as caesium (Cs⁺), or a combination thereof, the L component may be an organic cation such as 2-phenylethylammonium (C₆H₅C₂H₄NH₃⁺) or 1-napthylmethylammonium (C₁₀H₇CH₂NH₃⁺), the B component may be a divalent metal cation, such as lead (Pb⁺), tin (Sn⁺), copper (Cu⁺), europium (Eu⁺) or a combination thereof, and the X component may be a halide anion, such as I⁻, Br⁻, Cl⁻, or a combination thereof. (C₆H₅C₂H₄NH₃)₂(CH(NH₂)₂PbBr₃)ₙ₋₁PbBr₄ and (C₁₀H₇CH₂NH₃)₂(CH₃NH₃PbI₂Br)ₙ₋₁PbI₃Br are non-limiting examples of metal halide perovskite material with a layered structure.

Where the number of layers n is large, for example n greater than approximately 10, perovskite material with a layered structure of L₂(ABX₃)ₙ₋₁BX₄ adopts a structure that is approximately equivalent to perovskite material with a 3D structure of ABX₃. As used herein, and as would generally be understood by one skilled in the art, perovskite material having a large number of layers may be referred to as a 3D perovskite material, even though it is recognized that such perovskite material has reduced dimensionality from n=∞. Where the number of layers n=1, perovskite material with a layered structure of L₂(ABX₃)ₙ₋₁BX₄ adopts a two-dimensional (2D) structure of L₂BX₄. Perovskite material having a single layer may be referred to as a 2D perovskite material. Where n is small, for example n in the range of approximately 2-10, perovskite material with a layered structure of L₂(ABX₃)ₙ₋₁BX₄ adopts a quasi-two-dimensional (Quasi-2D) structure. Perovskite material having a small number of layers may be referred to as a Quasi-2D perovskite material. Owing to quantum confinement effects, the energy band gap is lowest for layered perovskite material structures where n is highest.

Perovskite material may have any number of layers. Perovskites may comprise 2D perovskite material, Quasi-2D perovskite material, 3D perovskite material or a combination thereof. For example, perovskites may comprise an ensemble of layered perovskite materials having different numbers of layers. For example, perovskites may comprise an ensemble of Quasi-2D perovskite materials having different numbers of layers.

As used herein, the term “perovskite” further includes films of perovskite material. Films of perovskite material may be crystalline, polycrystalline or a combination thereof, with any number of layers and any range of grain or crystal size.

As used herein, the term “perovskite” further includes nanocrystals of perovskite material that have structure equivalent to or resembling the 3D perovskite structure of ABX₃ or the more general layered perovskite structure of L₂(ABX₃)ₙ₋₁BX₄. Nanocrystals of perovskite material may include perovskite nanoparticles, perovskite nanowires, perovskite nanoplatelets, or a combination thereof. Nanocrystals of perovskite material may be of any shape or size, with any number of layers and any range of grain or crystal sizes. For a nanocrystal of perovskite material, the distribution of L cations may differ from that of perovskite material with a formal layered structure of L₂(ABX₃)ₙ₋₁BX₄. For example, in a nanocrystal of perovskite material, there may be a greater proportion of L cations arranged along the sides of the nanocrystal.

Several types of perovskite material may be stimulated to emit light in response to optical or electrical excitation. That is to say that perovskite light emitting material may be photoluminescent or electroluminescent. This nomenclature may differ slightly from that used by other sources.

One example of a perovskite light emitting material that emits red light is methylammonium lead iodide (CH₃NH₃PbI₃). One example of a perovskite light emitting material that emits green light is formamidinium lead bromide (CH(NH₂)₂PbBr₃). One example of a perovskite light emitting material that emits blue light is methylammonium lead chloride (CH₃NH₃PbCI₃).

In general, PeLED devices may be photoluminescent or electroluminescent. The term “PeLED” may be used to describe single emissive unit electroluminescent devices that comprise electroluminescent perovskite light emitting material. The term “PeLED” may also be used to describe stacked electroluminescent devices or one or more emissive units of stacked electroluminescent devices that comprise electroluminescent perovskite light emitting material. This nomenclature may differ slightly from that used by other sources.

The proposed display design may also be incorporated into displays comprising I-LEDs that comprise inorganic light emitting materials. As used herein, “inorganic” includes bulk crystalline semiconductor materials, including gallium arsenide (GaAs), aluminium gallium arsenide (AlGaAs), gallium arsenide phosphide (GaAsP), aluminium gallium indium phosphide (AlGalnP), gallium phosphide (GaP), aluminium gallium phosphide (AlGaP), gallium nitride (GaN), indium gallium nitride (InGaN) and zinc selenide (ZnSe). As used herein, “inorganic” does not include “quantum dot” or “perovskite” material, which are defined separately herein.

Inherent properties of inorganic light emitting materials render them well-suited to the herein disclosed display architecture. I-LEDs offer potential advantages of OLED, QLEDs and PeLEDs, including higher efficiency and brightness as well as improved stability for longer lifetime displays.

The proposed display design may also be incorporated into displays comprising pixels and sub-pixels of any dimensions, including MicroLED, MiniLED and NanoLED displays, and any of these displays may include any type of light emitting materials and devices, including organic, quantum dot, perovskite and inorganic materials in OLEDs, QLEDs, PeLEDs and I-LEDs. MicroLEDs, MiniLEDs and NanoLEDs are particularly well suited to high-resolution displays such as those used in headsets for AR/VR applications.

As used herein, “top” means furthest away from the substrate, while “bottom” means closest to the substrate. Where a first material, layer, unit, region, sub-pixel or device is described as “disposed over” a second material, layer, unit, region, sub-pixel or device, at least a portion of the first material, layer, unit, region, sub-pixel or device is disposed further away from the substrate than at least a portion of the second material, layer, unit, region, sub-pixel or device, and at least a portion of the first material, layer, unit, region, sub-pixel or device geometrically overlaps at least a portion of the second material, layer, unit, region, sub-pixel or device. There may be other materials, layers, units, regions, sub-pixels or devices in-between, unless it is specified that the first material, layer, unit, region, sub-pixel or device is “in contact with” the second material, layer, unit, region, sub-pixel or device.

As used herein, “solution processible” means capable of being dissolved, dispersed or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) and electron affinities (EA) are measured as negative energies relative to a vacuum level, a higher HOMO energy level corresponds to an IP that is less negative. Similarly, a higher LUMO energy level corresponds to an EA that is less negative. On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. The definitions of HOMO and LUMO energy levels therefore follow a different convention than work functions.

As used herein, and as would be generally understood by one skilled in the art, an LED may be referred to as a “stacked” LED if two or more emissive units are disposed over one another and are separated by one or more charge generation layers (CGLs) within the layer structure of the LED. A CGL may be single layer or may comprise multiple layers, including p-doped layers, n-doped layers, hole injection layers, hole transport layers, anodes or cathodes. A CGL may further comprise one or more electrically insulating layers that electrically isolate layers or regions of the CGL. In particular, a CGL may comprise an anode and a cathode with an electrically insulating layer disposed in between. A CGL may comprise the upper electrode of the lower emissive unit and the lower electrode of the upper emissive unit. A CGL may or may not be independently electrically addressed. In some sources, especially where the CGL is independently electrically addressed, a CGL may be referred to as a middle electrode. It should be understood that the terms “CGL” and “middle electrode” may be used interchangeably, and as used herein a middle electrode is considered to be a CGL. In some sources, a stacked LED may be referred to as a tandem LED. It should be understood that the terms “stacked” and “tandem” may be used interchangeably, and as used herein, a tandem LED is also considered to be a stacked LED. This nomenclature may differ slightly from that used by other sources.

As used herein, and as would be generally understood by one skilled in the art, “colour gamut” is the range of colours which can be accurately rendered in a colour space or by a display. Colour gamut is usually depicted by an enclosed area of the primary colours of the display on a chromaticity diagram, such as depicted in FIG. 4 for the DCI-P3 and Rec. 2020 colour gamuts in the CIE 1931 (x, y) chromaticity diagram. As used herein, a colour gamut may be considered “wider” if a larger range of colours can be accurately rendered by the gamut and it has a larger enclosed area on the CIE 1976 (u′, v′) chromaticity diagram. As used herein, a colour gamut may be considered “narrower” if a smaller range of colours can be accurately rendered by the gamut and it has a smaller enclosed area on the CIE 1976 (u′, v′) chromaticity diagram.

### SUMMARY

A display is provided. In one embodiment, the display comprises an arrangement of pixels, each pixel comprising: a first region configured to emit red light of a first chromaticity having first CIE 1931 (x, y) chromaticity coordinates of (x1, y1); a second region configured to emit red light of a second chromaticity having second CIE 1931 (x, y) chromaticity coordinates of (x2, y2); a third region configured to emit green light of a third chromaticity having third CIE 1931 (x, y) chromaticity coordinates of (x3, y3); a fourth region configured to emit green light of a fourth chromaticity having fourth CIE 1931 (x, y) chromaticity coordinates of (x4, y4); a fifth region configured to emit blue light of a fifth chromaticity having fifth CIE 1931 (x, y) chromaticity coordinates of (x5, y5); and a sixth region configured to emit blue light of a sixth chromaticity having sixth CIE 1931 (x, y) chromaticity coordinates of (x6, y6); wherein the second chromaticity is different to the first chromaticity; the fourth chromaticity is different to the third chromaticity; and the sixth chromaticity is different to the fifth chromaticity; wherein the first, third and fifth chromaticities define the primary colours of a first colour gamut; the second, fourth and sixth chromaticities define the primary colours of a second colour gamut; and: the area of the first colour gamut is less than 55% of the area of the second colour gamut in the CIE 1931 (x, y) chromaticity diagram.

A display is provided. In one embodiment, the display comprises an arrangement of pixels, each pixel comprising: a first region configured to emit red light of a first chromaticity having first CIE 1931 (x, y) chromaticity coordinates of (x1, y1); a second region configured to emit red light of a second chromaticity having second CIE 1931 (x, y) chromaticity coordinates of (x2, y2); a third region configured to emit green light of a third chromaticity having third CIE 1931 (x, y) chromaticity coordinates of (x3, y3); a fourth region configured to emit green light of a fourth chromaticity having fourth CIE 1931 (x, y) chromaticity coordinates of (x4, y4); a fifth region configured to emit blue light of a fifth chromaticity having fifth CIE 1931 (x, y) chromaticity coordinates of (x5, y5); and a sixth region configured to emit blue light of a sixth chromaticity having sixth CIE 1931 (x, y) chromaticity coordinates of (x6, y6); wherein the second chromaticity is different to the first chromaticity; the fourth chromaticity is different to the third chromaticity; and the sixth chromaticity is different to the fifth chromaticity; wherein the first, third and fifth chromaticities define the primary colours of a first colour gamut; the second, fourth and sixth chromaticities define the primary colours of a second colour gamut; the area of the first colour gamut is less than 55% of the area of the second colour gamut in the CIE 1931 (x, y) chromaticity diagram; the first colour gamut and the second colour gamut both enclose the D65 white point; and the fifth region emits blue light with CIE 1931 x coordinate x5 in the range of 0.075 to 0.155 and CIE 1931 y coordinate y5 in the range of 0.081 to 0.245.

In one embodiment, the area of the first colour gamut is less than 45% of the area of the second colour gamut in the CIE 1931 (x, y) chromaticity diagram. In one embodiment, the area of the first colour gamut is less than 35% of the area of the second colour gamut in the CIE 1931 (x, y) chromaticity diagram.

In one embodiment, the second chromaticity coordinates (x2, y2) are not contained within a one-step MacAdam ellipse that is centralized on the first chromaticity coordinates (x1, y1); the fourth chromaticity coordinates (x4, y4) are not contained within a one-step MacAdam ellipse that is centralized on the third chromaticity coordinates (x3, y3); and the sixth chromaticity coordinates (x6, y6) are not contained within a one-step MacAdam ellipse that is centralized on the fifth chromaticity coordinates (x5, y5).

In one embodiment, the second chromaticity coordinates (x2, y2) are not contained within a three-step MacAdam ellipse that is centralized on the first chromaticity coordinates (x1, y1); the fourth chromaticity coordinates (x4, y4) are not contained within a three-step MacAdam ellipse that is centralized on the third chromaticity coordinates (x3, y3); and the sixth chromaticity coordinates (x6, y6) are not contained within a three-step MacAdam ellipse that is centralized on the fifth chromaticity coordinates (x5, y5).

In one embodiment, the first region emits light having a first peak wavelength; the second region emits light having a second peak wavelength; the third region emits light having a third peak wavelength; the fourth region emits light having a fourth peak wavelength; the fifth region emits light having a fifth peak wavelength; and the sixth region emits light having a sixth peak wavelength; wherein the second peak wavelength is at least 4 nm greater the first peak wavelength; the fourth peak wavelength is at least 4 nm less than the third peak wavelength; and the sixth peak wavelength is at least 4 nm less than the fifth peak wavelength.

In one embodiment, the first CIE 1931 (x, y) chromaticity coordinates (x1, y1) may be converted to first CIE 1976 (u′, v′) chromaticity coordinates (u1, v1); the second CIE 1931 (x, y) chromaticity coordinates (x2, y2) may be converted to second CIE 1976 (u′, v′) chromaticity coordinates (u2, v2); the third CIE 1931 (x, y) chromaticity coordinates (x3, y3) may be converted to third CIE 1976 (u′, v′) chromaticity coordinates (u3, v3); the fourth CIE 1931 (x, y) chromaticity coordinates (x4, y4) may be converted to fourth CIE 1976 (u′, v′) chromaticity coordinates (u4, v4); the fifth CIE 1931 (x, y) chromaticity coordinates (x5, y5) may be converted to fifth CIE 1976 (u′, v′) chromaticity coordinates (u5, v5); and the sixth CIE 1931 (x, y) chromaticity coordinates (x6, y6) may be converted to sixth CIE 1976 (u′, v′) chromaticity coordinates (u6, v6); wherein the first chromaticity coordinates (u1, v1) and the second chromaticity coordinates (u2, v2) are sufficiently different such that the difference in chromaticity as defined by Δuv is 0.010 or more; the third chromaticity coordinates (u3, v3) and the fourth chromaticity coordinates (u4, v4) are sufficiently different such that the difference in chromaticity as defined by Δuv is 0.010 or more; and the fifth chromaticity coordinates (u5, v5) and the sixth chromaticity coordinates (u6, v6) are sufficiently different such that the difference in chromaticity as defined by Δuv is 0.010 or more.

In one embodiment, the first (u1, v1), third (u3, v3) and fifth (u5, v5) chromaticities define the primary colours of the first colour gamut; the second (u2, v2), fourth (u4, v4) and sixth (u6, v6) chromaticities define the primary colours of the second colour gamut; and the area of the first colour gamut is less than 50% of the area of the second colour gamut in the CIE 1976 (u′, v′) chromaticity diagram.

In one embodiment, the area of the first colour gamut is less than 40% of the area of the second colour gamut in the CIE 1976 (u′, v′) diagram. In one embodiment, the area of the first colour gamut is less than 25% of the area of the second colour gamut in the CIE 1976 (u′, v′) diagram.

In one embodiment, the first region and the second region both emit red light with a peak wavelength in the range of 580 nm to 780 nm; the third region and the fourth region both emit green light with a peak wavelength in the range of 500 nm to 580 nm; and the fifth region and the sixth region both emit blue light with a peak wavelength in the range of 380 nm to 500 nm.

In one embodiment, the first region emits lighter red light, and the second region emits deeper red light; the third region emits lighter green light, and the fourth region emits deeper green light; and the fifth region emits lighter blue light, and the sixth region emits deeper blue light.

In one embodiment, the first region emits red light with a peak wavelength in the range of 580 nm to 610 nm and the second region emits red light with a peak wavelength in the range of 610 nm to 780 nm; the third region emits green light with a peak wavelength in the range of 540 nm to 580 nm and the fourth region emits green light with a peak wavelength in the range of 500 nm to 540 nm; and the fifth region emits blue light with a peak wavelength in the range of 470 nm to 500 nm and the sixth region emits blue light with a peak wavelength in the range of 380 nm to 470 nm.

In one embodiment, the third region emits green light with a peak wavelength in the range of 550 nm to 560 nm. In one embodiment, the third region emits green light with a peak wavelength in the range of 555 nm to 557 nm.

In one embodiment, the first region emits red light with a peak wavelength in the range of 580 nm to 600 nm; the third region emits green light with a peak wavelength in the range of 550 nm to 560 nm; and the fifth region emits blue light with a peak wavelength in the range of 465 nm to 485 nm.

In one embodiment, the first region emits red light with a peak wavelength in the range of 585 nm to 595 nm; the third region emits green light with a peak wavelength in the range of 550 nm to 560 nm; and the fifth region emits blue light with a peak wavelength in the range of 470 nm to 480 nm.

In one embodiment, the first region emits red light with a CIE 1931 x coordinate of less than 0.640 and the second region emits red light with a CIE 1931 x coordinate of 0.640 or more; the third region emits green light with a CIE 1931 y coordinate of less than 0.650 and the fourth region emits green light with a CIE 1931 y coordinate of 0.650 or more; and the fifth region emits blue light with a CIE 1931 y coordinate of more than 0.080 and the sixth region emits blue light with a CIE 1931 y coordinate of 0.080 or less.

In one embodiment, the first region emits red light with CIE 1931 x coordinate in the range of 0.500 to 0.575 and CIE 1931 y coordinate in the range of 0.425 to 0.500; the third region emits green light with CIE 1931 x coordinate in the range of 0.335 to 0.415 and CIE 1931 y coordinate in the range of 0.575 to 0.649; and the fifth region emits blue light with CIE 1931 x coordinate in the range of 0.075 to 0.155 and CIE 1931 y coordinate in the range of 0.081 to 0.245.

In one embodiment, the first region emits red light with CIE 1931 x coordinate in the range of 0.515 to 0.560 and CIE 1931 y coordinate in the range of 0.440 to 0.485; the third region emits green light with CIE 1931 x coordinate in the range of 0.355 to 0.395 and CIE 1931 y coordinate in the range of 0.595 to 0.635; and the fifth region emits blue light with CIE 1931 x coordinate in the range of 0.100 to 0.140 and CIE 1931 y coordinate in the range of 0.110 to 0.150.

In one embodiment, the second colour gamut is the DCI-P3 colour gamut. In one embodiment, the second colour gamut is the Rec. 2020 colour gamut. In one embodiment, the first colour gamut and the second colour gamut both enclose the D65 white point.

In one embodiment, all of the first, second, third, fourth, fifth and sixth regions comprise organic LEDs (OLEDs). In one embodiment, all of the first, second, third, fourth, fifth and sixth regions comprise inorganic LEDs (I-LEDs). In one embodiment, all of the first, second, third, fourth, fifth and sixth regions comprise quantum dot LEDs (QLEDs) or perovskite LEDs (PeLEDs). In one embodiment, all of the first, second, third, fourth, fifth and sixth regions comprise MiniLEDs, MicroLEDs or NanoLEDs.

In one embodiment, all of the first, second, third, fourth, fifth and sixth regions have the same surface area. In one embodiment, at least one of the first, second, third, fourth, fifth and sixth regions has a surface area different from another of the first, second, third, fourth, fifth and sixth regions.

In one embodiment, the first region comprises a first sub-pixel that comprises a first LED that is configured to emit red light of the first chromaticity; the second region comprises a second sub-pixel that comprises a second LED that is configured to emit red light of the second chromaticity; the third region comprises a third sub-pixel that comprises a third LED that is configured to emit green light of the third chromaticity; the fourth region comprises a fourth sub-pixel that comprises a fourth LED that is configured to emit green light of the fourth chromaticity; the fifth region comprises a fifth sub-pixel that comprises a fifth LED that is configured to emit blue light of the fifth chromaticity; and the sixth region comprises a sixth sub-pixel that comprises a sixth LED that is configured to emit blue light of the sixth chromaticity; wherein each of the first, second, third, fourth, fifth and sixth LEDs comprise: a first electrode; a second electrode; and an emissive layer; wherein the emissive layer is disposed over the first electrode; the second electrode is disposed over the emissive layer; and none of the first, second, third, fourth, fifth or sixth LEDs are disposed over each other.

In one embodiment, the first region comprises a first emissive unit that is configured to emit red light of the first chromaticity; the second region comprises a second emissive unit that is configured to emit red light of the second chromaticity; the third region comprises a third emissive unit that is configured to emit green light of the third chromaticity; the fourth region comprises a fourth emissive unit that is configured to emit green light of the fourth chromaticity; the fifth region comprises a fifth emissive unit that is configured to emit blue light of the fifth chromaticity; and the sixth region comprises a sixth emissive unit that is configured to emit blue light of the sixth chromaticity; wherein a first sub-pixel comprises a first stacked LED comprising the first and second emissive units; a second sub-pixel comprises a second stacked LED comprising the third and fourth emissive units; and a third sub-pixel comprises a third stacked LED comprising the fifth and sixth emissive units; wherein the first stacked LED comprises: a first electrode; a second electrode; the first emissive unit comprising a first emissive layer; the second emissive unit comprising a second emissive layer; and a charge generation layer; wherein the first emissive unit, the second emissive unit and the charge generation layer are all disposed between the first electrode and the second electrode; the first emissive unit is disposed over the second emissive unit, or vice versa; the first emissive unit and the second emissive unit are separated by the charge generation layer; and the first emissive unit and the second emissive unit are independently addressed and may emit light independently of each other; the second stacked LED comprises: a first electrode; a second electrode; the third emissive unit comprising a third emissive layer; the fourth emissive unit comprising a fourth emissive layer; and a charge generation layer; wherein the third emissive unit, the fourth emissive unit and the charge generation layer are all disposed between the first electrode and the second electrode; the third emissive unit is disposed over the fourth emissive unit, or vice versa; the third emissive unit and the fourth emissive unit are separated by the charge generation layer; and the third emissive unit and the fourth emissive unit are independently addressed and may emit light independently of each other; and a third stacked LED comprises: a first electrode; a second electrode; the fifth emissive unit comprising a fifth emissive layer; the sixth emissive unit comprising a sixth emissive layer; and a charge generation layer; wherein the fifth emissive unit, the sixth emissive unit and the charge generation layer are all disposed between the first electrode and the second electrode; the fifth emissive unit is disposed over the sixth emissive unit, or vice versa; the fifth emissive unit and the sixth emissive unit are separated by the charge generation layer; and the fifth emissive unit and the sixth emissive unit are independently addressed and may emit light independently of each other.

A consumer product is provided. In one embodiment, the consumer product comprises the display disclosed herein.

### DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing. Embodiments of the present disclosure will now be described, by way of example only, with reference to the following:

FIG. 1 depicts a light emitting device.

FIG. 2 depicts an inverted light emitting device.

FIG. 3 depicts a rendition of the CIE 1931 (x, y) chromaticity diagram.

FIG. 4 depicts a rendition of the CIE 1931 (x, y) chromaticity diagram that also shows colour gamuts for (a) DCI-P3 and (b) Rec. 2020.

FIG. 5 depicts exemplary electroluminescence emission spectra for light and deep red, green and blue LEDs plotted against the photopic luminous efficiency function.

FIG. 6 depicts a rendition of the CIE 1931 (x, y) chromaticity diagram that also shows 10-step MacAdam ellipses.

FIG. 7 depicts a rendition of the CIE 1931 (x, y) chromaticity diagram that also shows colour gamuts for (a) DCI-P3 and (b) Rec. 2020 with chromaticity coordinates for exemplary red, green and blue OLEDs.

FIG. 8 depicts an exemplary arrangement of sub-pixels of a display.

FIG. 9 depicts exemplary LEDs of sub-pixels of a display.

FIG. 10 depicts a further exemplary arrangement of sub-pixels of a display.

FIG. 11 depicts exemplary stacked LEDs of sub-pixels of a display.

FIG. 12 depicts exemplary colour gamuts for sub-pixels that emit lighter red, green and blue light and sub-pixels that emit deeper red, green and blue light in the CIE 1931 (x, y) chromaticity diagram, with (a) non-optimized and (b) optimized lighter red, green and blue chromaticities.

FIG. 13 depicts exemplary arrangements of sub-pixels of a display, wherein the sub-pixels have different surface areas.

FIG. 14 depicts exemplary stacked light emitting devices having two independently addressed emissive units.

FIG. 15 depicts distribution of typical image chromaticity in the 1931 CIE (x, y) chromaticity diagram.

FIG. 16 depicts further exemplary colour gamuts for sub-pixels that emit lighter red, green and blue light and sub-pixels that emit deeper red, green and blue light in the CIE 1976 (u′, v′) chromaticity diagram, with (a) non-optimized and (b) optimized lighter red, green and blue chromaticities.

FIG. 17 depicts further exemplary electroluminescence emission spectra for optimized light red, green and blue and deep red, green and blue LEDs plotted against the photopic luminous efficiency function.

### DESCRIPTION OF EMBODIMENTS

The present invention relates to multi-primary colour displays, and in particular to multi-primary displays comprising regions that emit light of the same hue but different chromaticity.

Optionally, each region may comprise an OLED. Optionally, each region may comprise a QLED or PeLED. Optionally, each region may comprise an I-LED.

Device architectures and operating principles for OLEDs, QLEDs and PeLEDs are substantially similar. Each of these LEDs comprises at least one emissive layer disposed between and electrically connected to an anode and a cathode. For an OLED, the emissive layer comprises organic light emitting material. For a QLED, the emissive layer comprises quantum dot light emitting material. For a PeLED, the emissive layer comprises perovskite light emitting material. For each of these LEDs, when a current is applied, the anode injects holes, and the cathode injects electrons into the emissive layer(s). The injected holes and electrons each migrate towards the oppositely charged electrode. When an electron and a hole localize, an exciton, which is a localized electron-hole pair having an excited energy state, may be formed. Light is emitted if the exciton relaxes via a photo-emissive mechanism. Non-radiative mechanisms, such as thermal radiation and/or Auger recombination may also occur but are generally considered undesirable. Substantial similarity between device architectures and working principles required for OLEDs, QLEDs and PeLEDs facilitates the combination of OLEDs, QLEDs and PeLEDs in the pixel arrangement of a display.

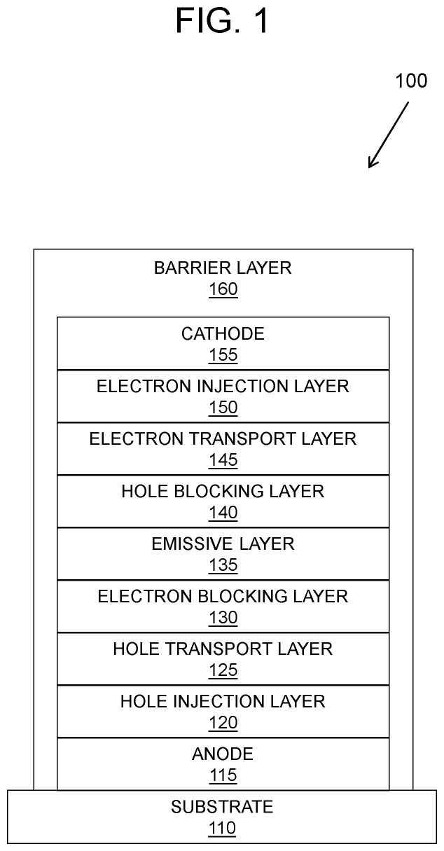

FIG. 1 shows an LED 100 with a single emissive unit. The LED 100 may be an OLED, QLED or PeLED. For an OLED, QLED or PeLED, device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a cathode 155 and a barrier layer 160. Device 100 may be fabricated by depositing the layers described in order. As the device 100 has anode 115 disposed under cathode 155, device 100 may be referred to as a “standard” device architecture. For an OLED, the emissive layer comprises organic light emitting material. For a QLED, the emissive layer comprises quantum dot light emitting material. For a PeLED, the emissive layer comprises perovskite light emitting material.

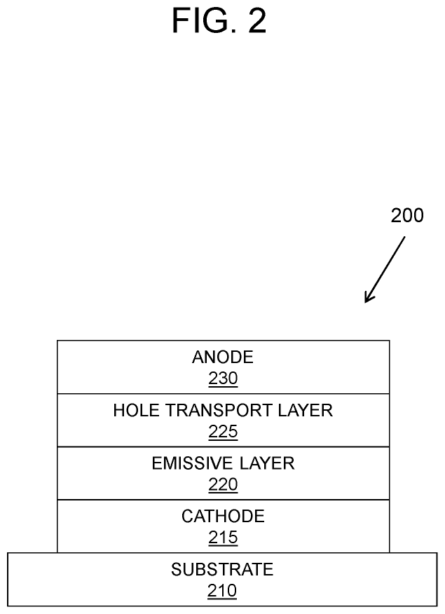

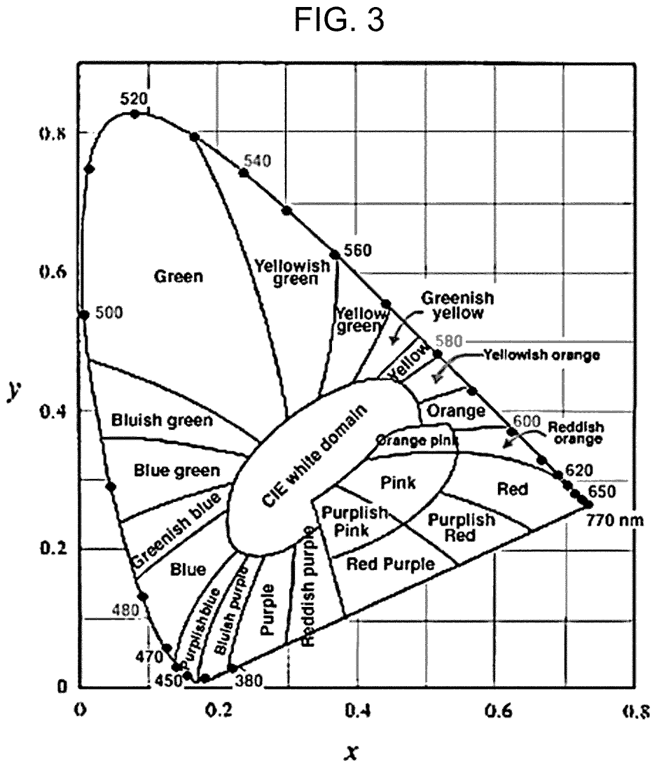

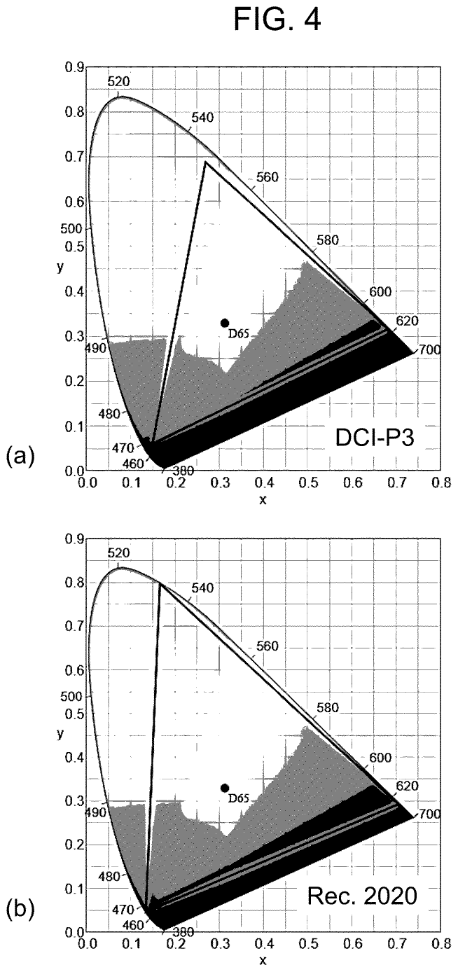

FIG. 2 shows an inverted LED 200 with a single emissive unit. The LED 200 may be an OLED, QLED or PeLED. For an OLED, QLED or PeLED, device 200 may include a substrate 210, a cathode 215, an emissive layer 220, a hole transport layer 225, and an anode 230. Device 200 may be fabricated by depositing the layers described in order. As the device 200 has cathode 215 disposed under anode 230, device 200 may be referred to as an “inverted” device architecture. For an OLED, the emissive layer comprises organic light emitting material. For a QLED, the emissive layer comprises quantum dot light emitting material. For a PeLED, the emissive layer comprises perovskite light emitting material. Materials similar to those described with respect to device 100 may be used in the corresponding layers of device 200. FIG. 2 provides one example of how some layers may be omitted from the structure of an OLED, QLED or PeLED.

The simple layered structures illustrated in FIGS. 1 and 2 are provided by way of non-limiting examples, and it is understood that embodiments of the invention may be used in connection with a wide variety of other structures. The specific materials and structures described are exemplary in nature, and other materials and structures may be used. Functional LEDs, including OLEDs, QLEDs or PeLEDs may be achieved by combining the various layers described in different ways, or layers may be omitted entirely, based on factors such as performance, design and cost. Other layers, not specifically described, may also be included. Materials other than those specifically described may be used. Although many of the examples provided herein describe various layers as comprising a single material, it is understood that combinations of materials may be used. Also, the layers may have various sublayers. The names given to the various layers herein are not intended to be strictly limiting. For example, in a device, the hole transport layer may transport and inject holes into the emissive layer and may be described as a hole transport layer or a hole injection layer. OLEDs, PeLEDs and QLEDs are generally intended to emit light through at least one of the electrodes, and one or more transparent electrodes may be useful in such optoelectronic devices. For example, a transparent electrode material, such as indium tin oxide (ITO), may be used for the bottom electrode, while a transparent electrode material, such as a thin metallic layer of a blend of magnesium and silver (Mg:Ag), may be used for the top electrode. For a device intended to emit light only through the bottom electrode, the top electrode does not need to be transparent, and may be comprised of an opaque and/or reflective layer, such as a metal layer having a high reflectivity. Similarly, for a device intended only to emit light through the top electrode, the bottom electrode may be opaque and/or reflective, such as a metal layer having a high reflectivity. Where an electrode does not need to be transparent, using a thicker layer may provide better conductivity and may reduce voltage drop and/or Joule heating in the device, and using a reflective electrode may increase the amount of light emitted through the other electrode by reflecting light back towards the transparent electrode. A fully transparent device may also be fabricated, where both electrodes are transparent.

Devices fabricated in accordance with embodiments of the present invention may optionally comprise a substrate 110. The substrate 110 may comprise any suitable material that provides the desired structural and optical properties. The substrate 110 may be rigid or flexible. The substrate 110 may be flat or curved. The substrate 110 may be transparent, translucent or opaque. Preferred substrate materials are glass, plastic and metal foil. Other substrates, such as fabric and paper may be used. The material and thickness of the substrate 110 may be chosen to obtain desired structural and optical properties.

Devices fabricated in accordance with embodiments of the present invention may optionally comprise an anode 115. The anode 115 may comprise any suitable material or combination of materials known to the art, such that the anode 115 is capable of conducting holes and injecting them into the layers of the device. Preferred anode 115 materials include conductive metal oxides, such as indium tin oxide (ITO), indium zinc oxide (IZO) and aluminum zinc oxide (AlZnO), metals such as silver (Ag), aluminum (Al), aluminum-neodymium (Al:Nd), gold (Au) and alloys thereof, or a combination thereof. Other preferred anode 115 materials include graphene, carbon nanotubes, nanowires or nanoparticles, silver nanowires or nanoparticles, organic materials, such as poly(3,4-ethylenedioxythiophene):polystyrene sulfonate (PEDOT:PSS) and derivatives thereof, or a combination thereof. Compound anodes comprising one or more anode materials in a single layer may be preferred for some devices. Multilayer anodes comprising one or more anode materials in one or more layers may be preferred for some devices. One example of a multilayer anode is ITO/Ag/ITO. In a standard device architecture for OLEDs, QLEDs and PeLEDs, the anode 115 may be sufficiently transparent to create a bottom-emitting device, where light is emitted through the substrate. One example of a transparent anode commonly used in a standard device architecture is a layer of ITO. Another example of a transparent anode commonly used in a standard device architecture is ITO/Ag/ITO, where the Ag thickness is less than approximately 25 nm. By including a layer of silver of thickness less than approximately 25 nm, the anode may be transparent as well as partially reflective. When such a transparent and partially reflective anode is used in combination with a reflective cathode, such as Al, this may have the advantage of creating a microcavity within the device. A microcavity may provide one or more of the following advantages: an increased total amount of light emitted from device, and therefore higher efficiency and brightness; an increased proportion of light emitted in the forward direction, and therefore increased apparent brightness at normal incidence; and spectral narrowing of the emission spectrum, resulting in light emission with increased colour saturation. The anode 115 may be opaque and/or reflective. In a standard device architecture for OLEDs, QLEDs and PeLEDs, a reflective anode 115 may be preferred for some top-emitting devices to increase the amount of light emitted from the top of the device. One example of a reflective anode commonly used in a standard device architecture is a multilayer anode of ITO/Ag/ITO, where the Ag thickness is greater than approximately 80 nm. When such a reflective anode is used in combination with a transparent and partially reflective cathode, such as Mg:Ag, this may have the advantage of creating a microcavity within the device. The material and thickness of the anode 115 may be chosen to obtain desired conductive and optical properties. Where the anode 115 is transparent, there may be a range of thicknesses for a particular material that is thick enough to provide the desired conductivity, yet thin enough to provide the desired degree of transparency. Other materials and structures may be used.

Devices fabricated in accordance with embodiments of the present invention may optionally comprise a hole transport layer 125. The hole transport layer 125 may include any material capable of transporting holes. The hole transport layer 125 may be deposited by a solution process or by a vacuum deposition process. The hole transport layer 125 may be doped or undoped. Doping may be used to enhance conductivity.

Examples of undoped hole transport layers are N,N′-Di(1-naphthyl)-N,N′-diphenyl-(1,1′-biphenyl)-4,4′-diamine (NPD), poly[(9,9-dioctylfluorenyl-2,7-diyl)-co-(4,4′-(N-(4-sec-butylphenyl)diphenylamine (TFB), poly[N,N′-bis(4-butylphenyl)-N,N′-bis(phenyl)-benzidine] (poly-TPD), poly(9-vinylcarbazole) (PVK), 4,4′-Bis(N-carbazolyl)-1,1′-biphenyl (CBP), Spiro-OMeTAD and molybdenum oxide (MoO₃). One example of a doped hole transport layer is 4,4′,4″-tris[phenyl(m-tolyl)amino]triphenylamine (m-MTDATA) doped with F₄-TCNQ at a molar ratio of 50:1. One example of a solution-processed hole transport layer is PEDOT:PSS. Other hole transport layers and structures may be used.

Devices fabricated in accordance with embodiments of the present invention may optionally comprise an emissive layer 135. The emissive layer 135 may include any material capable of emitting light when a current is passed between anode 115 and cathode 155.

Several examples of fluorescent organic light emitting materials are described in European patent EP 0423283 B1. Several examples of phosphorescent organic light emitting materials are described in United States patent U.S. Pat. No. 6,303,238 B1 and United States patent U.S. Pat. No. 7,279,704 B2. Several examples of organic light emitting materials that emit through a TADF mechanism are described in Uoyama et al. Several examples of organic light emitting materials that emit through a Hyperfluorescence mechanism are described in Cheng et al.

Several examples of quantum dot light emitting materials are described in Kathirgamanathan et al. Several examples of perovskite light emitting materials are described in United States patent application US20220052262 A1. All of these citations are included herein by reference in their entirety.

Devices fabricated in accordance with embodiments of the present invention may optionally comprise an electron transport layer 145. The electron transport layer 145 may include any material capable of transporting electrons. The electron transport layer 145 may be deposited by a solution process or by a vacuum deposition process. The electron transport layer 145 may be doped or undoped. Doping may be used to enhance conductivity.

Examples of undoped electron transport layers are tris(8-hydroxyquinolinato)aluminum (Alq₃), 2,21,2″-(1,3,5-Benzinetriyl)-tris(1-phenyl-1-H-benzimidazole) (TPBi), 2,9-Dimethyl-4,7-diphenyl-1,10-phenanthroline (BCP), zinc oxide (ZnO) and titanium dioxide (TiO₃). One example of a doped electron transport layer is 4,7-diphenyl-1,10-phenanthroline (BPhen) doped with lithium (Li) at a molar ratio of 1:1. One example of a solution-processed electron transport layer is [6,6]-Phenyl C61 butyric acid methyl ester (PCBM). Other electron transport layers and structures may be used.

Devices fabricated in accordance with embodiments of the present invention may optionally comprise a cathode 155. The cathode 155 may comprise any suitable material or combination of materials known to the art, such that the cathode 155 is capable of conducting electrons and injecting them into the layers of the device. Preferred cathode 155 materials include metal oxides, such as indium tin oxide (ITO), indium zinc oxide (IZO) and fluorine tin oxide (FTO), metals, such as calcium (Ca), barium (Ba), magnesium (Mg) and ytterbium (Yb) or a combination thereof. Other preferred cathode 155 materials include metals such as silver (Ag), aluminum (Al), aluminum-neodymium (Al:Nd), gold (Au) and alloys thereof, or a combination thereof. Compound cathodes comprising one or more cathode materials in a single layer may be preferred from some devices. One example of a compound cathode is Mg:Ag. Multilayer cathodes comprising one or more cathode materials in one or more layers may be preferred for some devices. One example of a multilayer cathode is Ba/Al. In a standard device architecture for OLEDs, QLEDs and PeLEDs, the cathode 155 may be sufficiently transparent to create a top-emitting device, where light is emitted from the top of the device. One example of a transparent cathode commonly used in a standard device architecture is a compound layer of Mg:Ag. By using a compound of Mg:Ag, the cathode may be transparent as well as partially reflective. When such a transparent and partially reflective cathode is used in combination with a reflective anode, such as ITO/Ag/ITO, where the Ag thickness is greater than approximately 80 nm, this may have the advantage of creating a microcavity within the device. The cathode 155 may be opaque and/or reflective. In a standard device architecture for OLEDs, QLEDs and PeLEDs, a reflective cathode 155 may be preferred for some bottom-emitting devices to increase the amount of light emitted through the substrate from the bottom of the device. One example of a reflective cathode commonly used in a standard device architecture is Al. When such a reflective cathode is used in combination with a transparent and partially reflective anode, such as ITO/Ag/ITO, where the Ag thickness is less than approximately 25 nm, this may have the advantage of creating a microcavity within the device.

The material and thickness of the cathode 155 may be chosen to obtain desired conductive and optical properties. Where the cathode 155 is transparent, there may be a range of thicknesses for a particular material that is thick enough to provide the desired conductivity, yet thin enough to provide the desired degree of transparency. Other materials and structures may be used.

Devices fabricated in accordance with embodiments of the present invention may optionally comprise one or more blocking layers. Blocking layers may be used to reduce the number of charge carriers (electrons or holes) and/or excitons exiting the emissive layer. An electron blocking layer 130 may be disposed between the emissive layer 135 and the hole transport layer 125 to block electrons from leaving the emissive layer 135 in the direction of the hole transport layer 125. Similarly, a hole blocking layer 140 may be disposed between the emissive layer 135 and the electron transport layer 145 to block holes from leaving the emissive layer 135 in the direction of the electron transport layer 145. Blocking layers may also be used to block excitons from diffusing from the emissive layer. As used herein, and as would be understood by one skilled in the art, the term “blocking layer” means that the layer provides a barrier that significantly inhibits transport of charge carriers and/or excitons, without suggesting that the layer completely blocks the charge carriers and/or excitons. The presence of such a blocking layer in a device may result in substantially higher efficiencies as compared to a similar device lacking a blocking layer. A blocking layer may also be used to confine emission to a desired region of a device. A blocking layer may also perform a charge transport function.

Devices fabricated in accordance with embodiments of the present invention may optionally comprise one or more injection layers. Generally, injection layers are comprised of one or more materials that may improve the injection of charge carriers from one layer, such as an electrode, into an adjacent layer. Injection layers may also perform a charge transport function.

In device 100, the hole injection layer 120 may be any layer that improves the injection of holes from the anode 115 into the hole transport layer 125. Examples of materials that may be used as a hole injection layer are Copper (II) phthalocyanine (CuPc) and 1,4,5,8,9,11-Hexaazatriphenylenehexacarbonitrile (HATCN), which may be vapor deposited, and polymers, such as PEDOT:PSS, which may be deposited from solution. Another example of a material that may be used as a hole injection layer is molybdenum oxide (MoO₃).

A hole injection layer (HIL) 120 may comprise a charge carrying component having HOMO energy level that favourably matches, as defined by their herein-described relative IP energies, with the adjacent anode layer on one side of the HIL, and the hole transporting layer on the opposite side of the HIL. The “charge carrying component” is the material responsible for the HOMO energy level that actually transports the holes. This material may be the base material of the HIL, or it may be a dopant. Using a doped HIL allows the dopant to be selected for its electrical properties, and the host to be selected for morphological properties, such as ease of deposition, wetting, flexibility, toughness, and others. Preferred properties of the HIL material are such that holes can be efficiently injected from the anode into the HIL material. The charge carrying component of the HIL 120 preferably has an IP not more than about 0.5 eV greater than the IP of the anode material. Similar conditions apply to any layer into which holes are being injected. HIL materials are further distinguished from conventional hole transporting materials that are typically used in the hole transporting layer of an OLED, QLED or PeLED in that such HIL materials may have a hole conductivity that is substantially less than the hole conductivity of conventional hole transporting materials. The thickness of the HIL 120 of the present invention may be thick enough to planarize the anode and enable efficient hole injection, but thin enough not to hinder transportation of holes. For example, an HIL thickness of as little as 10 nm may be acceptable. However, for some devices, an HIL thickness of up to 50 nm may be preferred.

In device 100, the electron injection layer 150 may be any layer that improves the injection of electrons from the cathode 155 into the electron transport layer 145. Examples of materials that may be used as an electron injection layer are inorganic salts, such as lithium fluoride (LiF), sodium fluoride (NaF), barium fluoride (BaF), caesium fluoride (CsF), and caesium carbonate (CsCO₃). Other examples of materials that may be used as an electron injection layer are metal oxides, such as zinc oxide (ZnO) and titanium oxide (TiO₂), and metals, such as calcium (Ca), barium (Ba), magnesium (Mg) and ytterbium (Yb). Other materials or combinations of materials may be used for injection layers. Depending on the configuration of a particular device, injection layers may be disposed at locations different than those shown in device 100.

Devices fabricated in accordance with embodiments of the present invention may optionally comprise a barrier layer 160. One purpose of the barrier layer 160 is to protect device layers from damaging species in the environment, including moisture, vapour and/or gasses. Optionally, the barrier layer 160 may be deposited over, under or next to the substrate, electrode, or any other parts of the device, including an edge. Optionally, the barrier layer 160 may be a bulk material such as glass or metal, and the bulk material may be affixed over, under of next to the substrate, electrode, or any other parts of the device. Optionally, the barrier layer 160 may be deposited onto a film, and the film may be affixed over, under of next to the substrate, electrode, or any other parts of the device. Where the barrier layer 160 is deposited onto a film, preferred film materials comprise glass, plastics, such as polyethylene terephthalate (PET) and polyethylene naphthalate (PEN) and metal foils. Where the barrier layer 160 is a bulk material or deposited onto a film, preferred materials used to affix the film or bulk material to the device include thermal or UV-curable adhesives, hot-melt adhesives and pressure sensitive adhesives.

The barrier layer 160 may be a bulk material or formed by various known deposition techniques, including sputtering, vacuum thermal evaporation, electron-beam deposition and chemical vapour deposition (CVD) techniques, such as plasma-enhanced chemical vapour deposition (PECVD) and atomic layer deposition (ALD). The barrier layer 160 may include compositions having a single phase as well as compositions having multiple phases. Any suitable material or combination of materials may be used for the barrier layer 160. The barrier layer 160 may incorporate organic or inorganic compounds or both. Preferred inorganic barrier layer materials include aluminum oxides such as Al₂O₃, silicon oxides such as SiO₂, silicon nitrides such as SiNₓ and bulk materials such as glasses and metals. Preferred organic barrier layer materials include polymers. The barrier layer 160 may comprise a single layer or multiple layers. Multilayer barriers comprising one or more barrier materials in one or more layers may be preferred for some devices. One preferred example of a multilayer barrier is a barrier comprising alternating layers of SiNₓ and a polymer, such as in the multilayer barrier SiNₓ/polymer/SiNₓ.

Unless otherwise specified, any one of the layers of the various embodiments may be deposited by any suitable method. Methods include vacuum thermal evaporation, sputtering, chemical vapor deposition, metal organic chemical vapor deposition, plasma enhanced chemical vapour deposition, epitaxy, molecular beam epitaxy, physical vapor deposition, electron beam physical vapour deposition, organic vapor phase deposition and organic vapour jet printing. Other suitable methods include pick-and-place as well as spincoating, blade-coating, slot-die-coating, inkjet printing and other solution-based processes.

Devices fabricated in accordance with embodiments of the invention may be incorporated into a wide range of consumer products. Optionally, devices may be used in displays for televisions, computer monitors, tablets, laptop computers, smart phones, cell phones, digital cameras, video recorders, smartwatches, fitness trackers, personal digital assistants, vehicle displays and other electronic devices. Optionally, devices may be used for micro-displays or heads-up displays for applications such as augmented reality (AR) and virtual reality (VR). Optionally, devices may be used in light panels for interior or exterior illumination and/or signaling, in smart packaging or in billboards.

Optionally, various control mechanisms may be used to control LEDs fabricated in accordance with the present invention, including passive matrix and active-matrix address schemes.

The materials and structures described herein may have applications in devices other than LEDs. For example, other optoelectronic devices such as solar cells, photodetectors, transistors or lasers may employ the materials and structures.

The present invention relates to multi-primary colour displays, and in particular to multi-primary displays comprising regions that emit light of the same hue but different chromaticity.

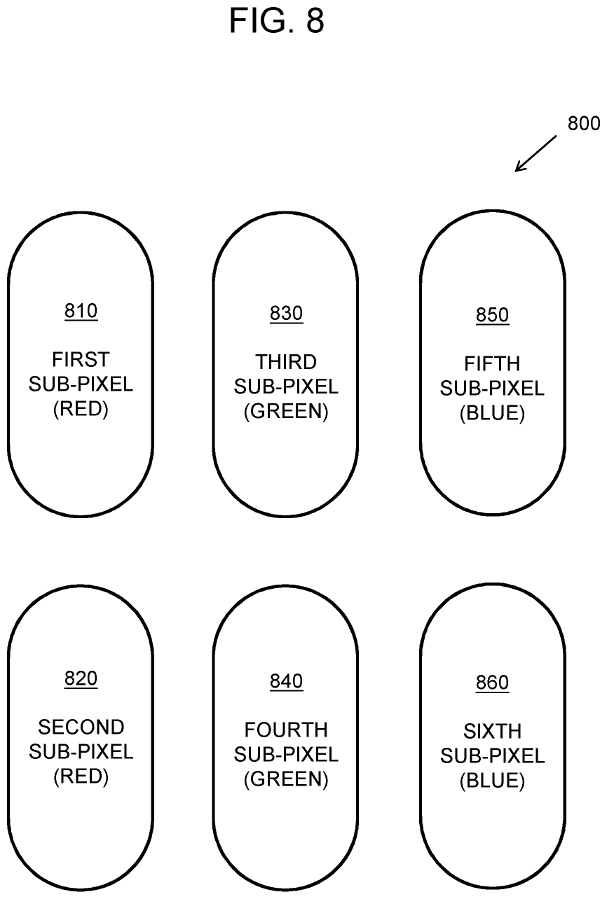

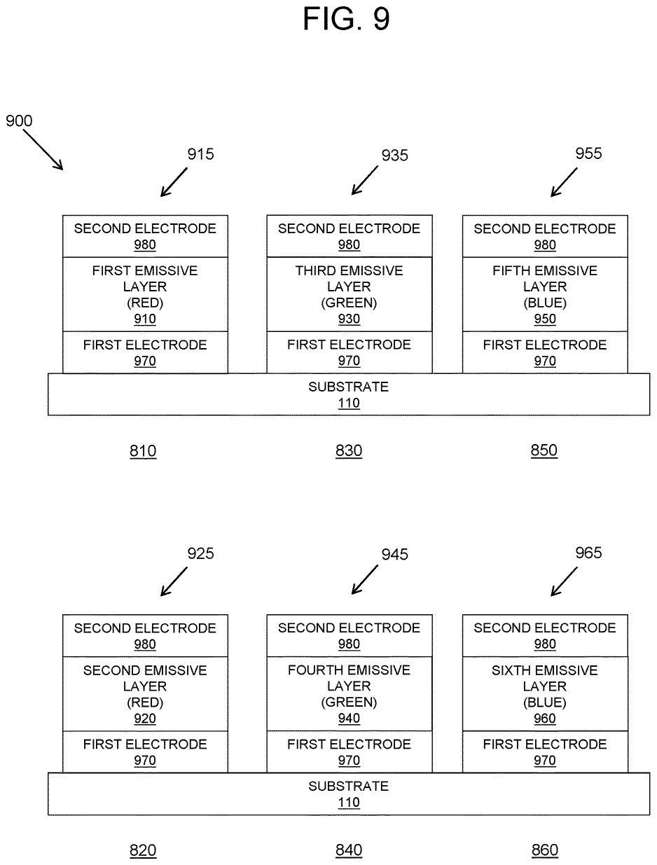

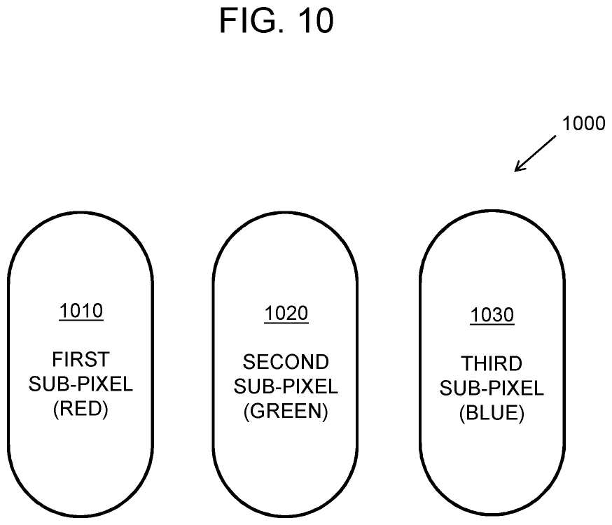

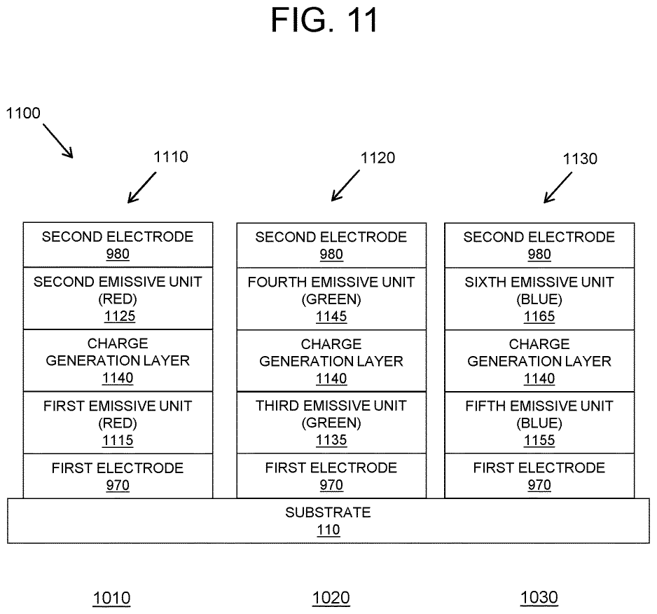

The invention may be understood with reference to arrangement 800 in FIG. 8, arrangement 900 in FIG. 9, arrangement 1000 in FIG. 10 and arrangement 1100 in FIG. 11. For simplicity, in FIG. 8, FIG. 9, FIG. 10 and FIG. 11 a region that comprises an emissive layer comprising light emitting material that emits red light is labelled “RED”, a region that comprises an emissive layer comprising light emitting material that emits green light is labelled “Green”, and a region that comprises an emissive layer comprising light emitting material that emits blue light is labelled “BLUE”. The red, green and blue regions may be further classified as “deeper” or “lighter” as defined herein.

In one embodiment, the display comprises an arrangement of pixels, each pixel comprising: a first region 915 or 1115 configured to emit red light of a first chromaticity having first CIE 1931 (x, y) chromaticity coordinates of (x1, y1); a second region 925 or 1125 configured to emit red light of a second chromaticity having second CIE 1931 (x, y) chromaticity coordinates of (x2, y2); a third region 935 or 1135 configured to emit green light of a third chromaticity having third CIE 1931 (x, y) chromaticity coordinates of (x3, y3); a fourth region 945 or 1145 configured to emit green light of a fourth chromaticity having fourth CIE 1931 (x, y) chromaticity coordinates of (x4, y4); a fifth region 955 or 1155 configured to emit blue light of a fifth chromaticity having fifth CIE 1931 (x, y) chromaticity coordinates of (x5, y5); and a sixth region 965 or 1165 configured to emit blue light of a sixth chromaticity having sixth CIE 1931 (x, y) chromaticity coordinates of (x6, y6); wherein the second chromaticity is different to the first chromaticity; the fourth chromaticity is different to the third chromaticity; and the sixth chromaticity is different to the fifth chromaticity; wherein the first, third and fifth chromaticities define the primary colours of a first colour gamut; the second, fourth and sixth chromaticities define the primary colours of a second colour gamut; and: the area of the first colour gamut is less than 55% of the area of the second colour gamut in the CIE 1931 (x, y) chromaticity diagram.

The red, green and blue regions may be red, green and blue LEDs, as depicted in FIG. 8 and FIG. 9. The red, green and blue regions may also be red, green and blue emissive units of red, green and blue stacked LEDs, as depicted in FIG. 10 and FIG. 11.

FIG. 8 and FIG. 9 depict an arrangement of red (810 and 820), green (830 and 840), and blue (850 and 860) sub-pixels that comprise red (915 and 925), green (935 and 945), and blue (955 and 965) LEDs of a display that may render images using the display design disclosed herein. Each LED comprises a substrate 110, a first electrode 970, a second electrode 980 and an emissive layer disposed between the first electrode 970 and second electrode 980. The first LED 915 comprises a first emissive layer 910 that emits red light of a first chromaticity. The second LED 925 comprises a second emissive layer 920 that emits red light of a second chromaticity. The third LED 935 comprises a third emissive layer 930 that emits green light of a third chromaticity. The fourth LED 945 comprises a fourth emissive layer 940 that emits green light of a fourth chromaticity. The fifth LED 955 comprises a fifth emissive layer 950 that emits blue light of a fifth chromaticity. The sixth LED 965 comprises a sixth emissive layer 960 that emits blue light of a sixth chromaticity.

In one embodiment, none of the first, second, third, fourth, fifth or sixth LEDs are disposed over each other.

In one embodiment, the first region comprises the first LED 915, the second region comprises the second LED 925, the third region comprises the third LED 935, the fourth region comprises the fourth LED 945, the fifth region comprises the fifth LED 955 and the sixth region comprises the sixth LED 965.

FIG. 10 and FIG. 11 depict an arrangement of red 1010, green 1020, and blue 1030 sub-pixels that comprise red 1110, green 1120 and blue 1130 stacked LEDs of a display that may render images as disclosed herein. Each stacked LED comprises a substrate 110, a first electrode 970, a second electrode 980, a charge generation layer 1140 and two emissive units, wherein the charge generation layer 1140 and the two emissive units are disposed between the first electrode 970 and second electrode 980, and the charge generation layer 1140 is disposed between the two emissive units. The first stacked LED 1110 comprises a first emissive unit 1115 that emits red light of a first chromaticity and a second emissive unit 1125 that emits red light of a second chromaticity. The second stacked LED 1120 comprises a third emissive unit 1135 that emits green light of a third chromaticity and a fourth emissive unit 1145 that emits green light of a fourth chromaticity. The third stacked LED 1130 comprises a fifth emissive unit 1155 that emits blue light of a fifth chromaticity and a sixth emissive unit 1165 that emits blue light of a sixth chromaticity.

In one embodiment, the second emissive unit 1125 may be disposed over the first emissive unit 1115, as depicted in FIG. 11, or vice versa. In one embodiment, the fourth emissive unit 1145 may be disposed over the third emissive unit 1135, as depicted in FIG. 11, or vice versa. In one embodiment, the sixth emissive unit 1165 may be disposed over the fifth emissive unit 1155, as depicted in FIG. 11, or vice versa.

In one embodiment, the first region comprises the first emissive unit 1115, the second region comprises the second emissive unit 1125, the third region comprises the third emissive unit 1135, the fourth region comprises the fourth emissive unit 1145, the fifth region comprises the fifth emissive unit 1155 and the sixth region comprises the sixth emissive unit 1165.

In one embodiment, the second chromaticity is different to the first chromaticity, the fourth chromaticity is different to the third chromaticity, and the sixth chromaticity is different to the fifth chromaticity.

In one embodiment, the first 915 or 1115 and second 925 or 1125 regions emit light of the same hue, but different chromaticity, the third 935 or 1135 and fourth 945 or 1145 regions emit light of the same hue but different chromaticity, and the fifth 955 or 1155 and sixth 965 or 1165 regions emit light of the same hue, but different chromaticity.

As used herein, “hue” refers to the degree to which light emitted by a light emitting material, emissive layer, emissive unit, region, sub-pixel or device can be described as similar to or different from the hues of red, green and blue. Materials, layers, units, regions, sub-pixels and devices may be described herein in reference to the hue of light they emit. As used herein, a “red” material, layer, unit, region, sub-pixel or device, refers to one that emits light with a red hue that has an emission spectrum with a peak wavelength in the range of 580 nm to 780 nm; a “green” material, layer, unit, region, sub-pixel or device, refers to one that emits light with a green hue that has an emission spectrum with a peak wavelength in the range of 500 nm to 580 nm; and a “blue” material, layer, unit, region, sub-pixel or device, refers to one that emits light with a blue hue that has an emission spectrum with a peak wavelength in the range of 380 nm to 500 nm.

This nomenclature may differ slightly from that used by other sources. In particular, some other sources may refer to “yellow” or “orange” materials, layers, units, regions, sub-pixels or devices that emit light that may be described as similar to the hue of yellow or orange. Such materials, layers, units, regions, sub-pixels or devices that may be referred to as yellow or orange by other sources, are herein considered to be either green or red, depending on the peak wavelength of the emission spectrum. For example, a material, layer, unit, region, sub-pixel or device that emits light that has an emission spectrum with a peak wavelength in the range of 560 nm to 580 nm is herein considered to be green, whereas other sources may consider this to be yellow. For example, a material, layer, unit, region, sub-pixel or device that emits light that has an emission spectrum with a peak wavelength in the range of 580 nm to 600 nm is herein considered to be red, whereas other sources may consider this to be orange. The reason for this simplification is that standard displays comprise only red, green and blue sub-pixels. The nomenclature used herein is therefore consistent with standard displays.

As used herein, two or more materials, layers, units, regions, sub-pixels or devices may be considered to have the same hue if the light they emit may be classified using the same hue or either red, green or blue. For example, if a first region emits red light and a second region emits red light then the first region and the second region may be considered to have the same hue. Likewise, if a first region emits green light and a second region emits green light then the first region and the second region may be considered to have the same hue. Likewise, if a first region emits blue light and a second region emits blue light then the first region and the second region may be considered to have the same hue.

As used herein, red, green and blue light emitted from materials, layers, units, regions, sub-pixels or devices may be referred to herein as “deep” or “deeper” or “light” or “lighter”, which refers to the relative saturation of the light.

In one embodiment, as used herein, “deep-red” light may refer to red light with a peak wavelength in the range of 610 nm to 780 nm, and “light-red” light may refer to red light with a peak wavelength in the range of 580 nm to 610 nm. In one embodiment, as used herein, “deep-green” light may refer to green light with a peak wavelength in the range of 500 nm to 540 nm, and “light-green” light may refer to green light with a peak wavelength in the range of 540 nm to 580 nm. In one embodiment, as used herein, “deep-blue” light may refer to blue light with a peak wavelength in the range of 380 nm to 470 nm, and “light-blue” light may refer to blue light with a peak wavelength in the range of 470 nm to 500 nm.

In one embodiment, as used herein, “deeper” red light refers to red light with relatively longer peak wavelength, and “lighter” red light refers to red light with relatively shorter peak wavelength. In one embodiment, as used herein, “deeper” green light refers to green light with relatively shorter peak wavelength, and “lighter” green light refers to green light with relatively longer peak wavelength (within the range of 500 nm to 580 nm). In one embodiment, as used herein, “deeper” blue light refers to blue light with relatively shorter peak wavelength, and “lighter” blue light refers to blue light with relatively longer peak wavelength.

In one embodiment, as used herein, “deep-red” light may refer to red light with a CIE 1931 x coordinate of 0.640 or more, and “light-red” light may refer to red light with a CIE 1931 x coordinate of less than 0.640. In one embodiment, as used herein, “deep-green” light may refer to green light with a CIE 1931 y coordinate of 0.650 or more, and “light-green” light may refer to green light with a CIE 1931 y coordinate of less than 0.650. In one embodiment, as used herein, “deep-blue” light may refer to blue light with a CIE 1931 y coordinate of 0.080 or less, and “light-blue” light may refer to blue light with a CIE 1931 y coordinate of more than 0.080.

Chromaticity refers to an objective specification of the quality of colour regardless of its luminance. As used herein, the “chromaticity” of light and may be visualized and quantified using the CIE 1931 (x, y) chromaticity diagram which depicts the CIE 1931 XYZ colour space. The chromaticity of light emitted from a material, layer, unit, region, sub-pixel or device may be quantified by its CIE 1931 (x, y) chromaticity coordinates on the CIE 1931 (x, y) chromaticity diagram.

As used herein, light emitted from materials, layers, units, regions, sub-pixels or devices may be considered to have “different” chromaticity if the light emitted is noticeably different to the average human eye. As used herein, light emitted from materials, layers, units, regions, sub-pixels or devices may be considered to have “the same” chromaticity if the light emitted is indistinguishable to the average human eye.

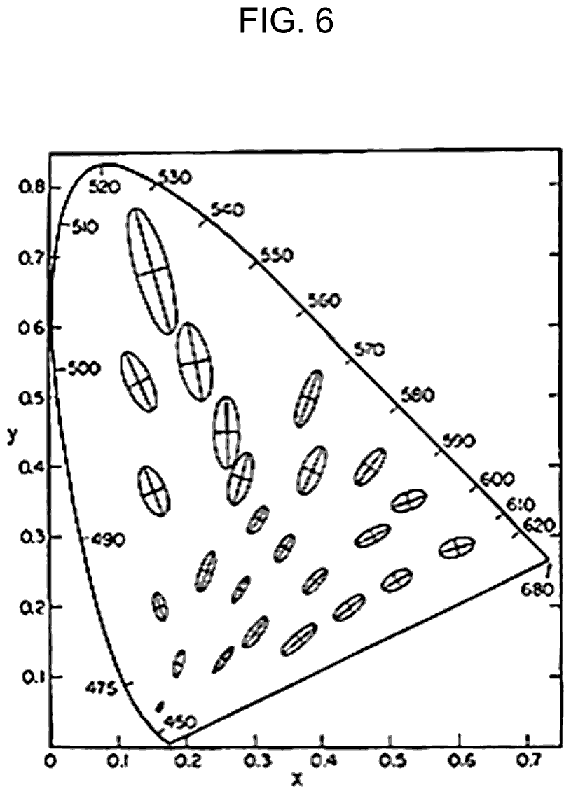

One suitable technique to quantify the chromaticity and difference of chromaticity of light is to use MacAdam ellipses. This may be visualized with reference to FIG. 6, which depicts MacAdam ellipses superimposed on the CIE 1931 (x, y) chromaticity diagram. Within the CIE 1931 (x, y) chromaticity diagram, a one-step MacAdam ellipse contains all chromaticity coordinates which are indistinguishable to the average human eye from the chromaticity coordinates at the centre of the ellipse. That is to say to the average human eye any light with chromaticity coordinates outside of a 1-step ellipse is noticeably different in chromaticity from the chromaticity at the centre of the ellipse. Tolerance may be introduced by extending the ellipses. For example, a two-step MacAdam ellipse has axes that are two times as large as for a one-step ellipse, and a ten-step MacAdam ellipse has axes that are ten times as large as for a one-step ellipse. All the MacAdam ellipses depicted in FIG. 6 are ten-step MacAdam ellipses.

In one embodiment, the second chromaticity coordinates (x2, y2) of light emitted from the second region 925 or 1125 are not contained within a one-step MacAdam ellipse that is centralized on the first chromaticity coordinates (x1, y1) of light emitted from the first region 915 or 1115; the fourth chromaticity coordinates (x4, y4) of light emitted from the fourth region 945 or 1145 are not contained within a one-step MacAdam ellipse that is centralized on the third chromaticity coordinates (x3, y3) of light emitted from the third region 935 or 1135; and the sixth chromaticity coordinates (x6, y6) of light emitted from the sixth region 965 or 1165 are not contained within a one-step MacAdam ellipse that is centralized on the fifth chromaticity coordinates (x5, y5) of light emitted from the fifth region 955 or 1155.

In one embodiment, the second chromaticity coordinates (x2, y2) of light emitted from the second region 925 or 1125 are not contained within a three-step MacAdam ellipse that is centralized on the first chromaticity coordinates (x1, y1) of light emitted from the first region 915 or 1115; the fourth chromaticity coordinates (x4, y4) of light emitted from the fourth region 945 or 1145 are not contained within a three-step MacAdam ellipse that is centralized on the third chromaticity coordinates (x3, y3) of light emitted from the third region 935 or 1135; and the sixth chromaticity coordinates (x6, y6) of light emitted from the sixth region 965 or 1165 are not contained within a three-step MacAdam ellipse that is centralized on the fifth chromaticity coordinates (x5, y5) of light emitted from the fifth region 955 or 1155.

One further suitable technique to characterize the difference in chromaticity of emitted light is to quantify the absolute difference in CIE 1976 (u′, v′) chromaticity coordinates in the CIE 1976 (u′, v′) chromaticity diagram of the CIELUV colour space. The CIE 1976 (u′, v′) chromaticity diagram is often used in preference over the CIE 1931 (x, y) chromaticity diagram because unlike the CIE 1931 (x, y) chromaticity diagram, in the CIE 1976 (u′, v′) chromaticity diagram, distance is approximately proportional to perceived difference in colour. The conversion between the colour spaces is simple: u′=4x/(−2x+12y+3) and v′=9y/(−2x+12y+3). Difference in chromaticity can be quantified as: Δuv=√(Δu′²+Δv′²)=√(u1−u2)²+(v1−v2)²), which is the distance in the CIE 1976 (u′, v′) chromaticity diagram of first chromaticity coordinates (u1, v1) from second chromaticity coordinates (u2, v2). As used herein, light emitted from a first region with first chromaticity coordinates (u1, v1) may be considered to have a different chromaticity to light emitted from a second region with second chromaticity coordinates (u2, v2) if the difference in chromaticity as defined by Δuv is 0.010 or more.

In one embodiment, the first CIE 1931 (x, y) chromaticity coordinates (x1, y1) may be converted to first CIE 1976 (u′, v′) chromaticity coordinates (u1, v1); the second CIE 1931 (x, y) chromaticity coordinates (x2, y2) may be converted to second CIE 1976 (u′, v′) chromaticity coordinates (u2, v2); the third CIE 1931 (x, y) chromaticity coordinates (x3, y3) may be converted to third CIE 1976 (u′, v′) chromaticity coordinates (u3, v3); the fourth CIE 1931 (x, y) chromaticity coordinates (x4, y4) may be converted to fourth CIE 1976 (u′, v′) chromaticity coordinates (u4, v4); the fifth CIE 1931 (x, y) chromaticity coordinates (x5, y5) may be converted to fifth CIE 1976 (u′, v′) chromaticity coordinates (u5, v5); and the sixth CIE 1931 (x, y) chromaticity coordinates (x6, y6) may be converted to sixth CIE 1976 (u′, v′) chromaticity coordinates (u6, v6); wherein the first chromaticity coordinates (u1, v1) of light emitted from the first region 915 or 1115 and the second chromaticity coordinates (u2, v2) of light emitted from the second region 925 or 1125 are sufficiently different such that the difference in chromaticity as defined by Δuv is 0.010 or more; the third chromaticity coordinates (u3, v3) of light emitted from the third region 935 or 1135 and the fourth chromaticity coordinates (u4, v4) of light emitted from the fourth region 945 or 1145 are sufficiently different such that the difference in chromaticity as defined by Δuv is 0.010 or more; and the fifth chromaticity coordinates (u5, v5) of light emitted from the fifth region 955 or 1155 and the sixth chromaticity coordinates (u6, v6) of light emitted from the sixth region 965 or 1165 are sufficiently different such that the difference in chromaticity as defined by Δuv is 0.010 or more.

One further suitable technique to characterize the difference in chromaticity of light emitted from regions is to measure the emission spectrum and compare peak emission wavelength.

In one embodiment, the first region 915 or 1115 emits light having a first peak wavelength; the second region 925 or 1125 emits light having a second peak wavelength; the third region 935 or 1135 emits light having a third peak wavelength; the fourth region 945 or 1145 emits light having a fourth peak wavelength; the fifth region 955 or 1155 emits light having a fifth peak wavelength; and the sixth region 965 or 1155 emits light having a sixth peak wavelength; wherein the second peak wavelength is at least 4 nm greater than the first peak wavelength; the fourth peak wavelength is at least 4 nm less than the third peak wavelength; and the sixth peak wavelength is at least 4 nm less than the fifth peak wavelength.

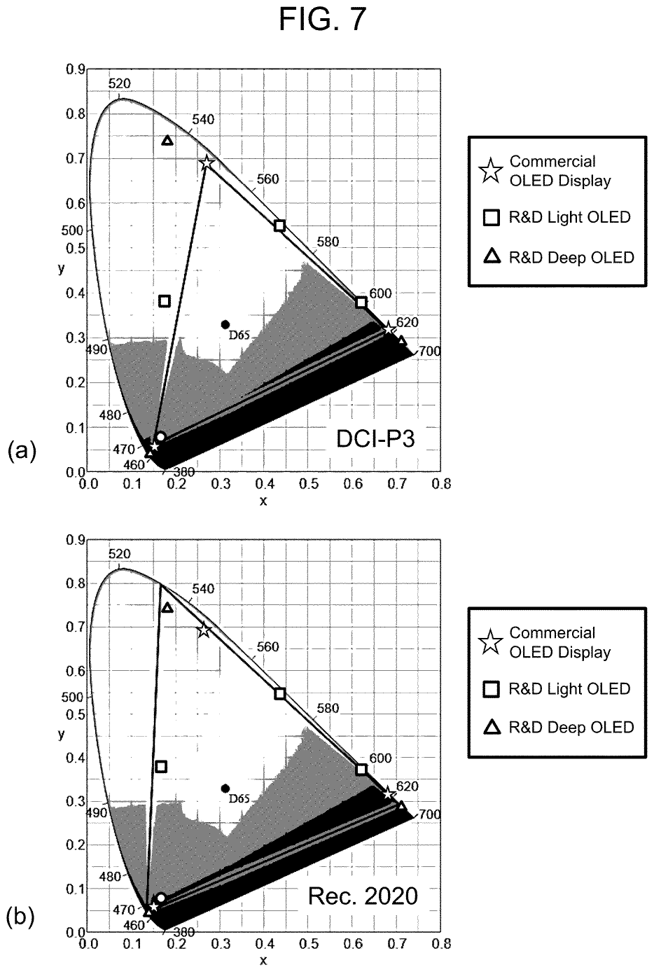

The proposed display design is ideally suited to rendering images on OLED displays. The proposed display design may also be used to render images on I-LED, QLED or PeLED displays. One or more advantages of including OLEDs in the display may be demonstrated using the data shown in Table 1 and FIG. 7.

Table 1 shows CIE 1931 (x, y) chromaticity coordinates for exemplary light and deep red, green and blue OLED devices. Also included in Table 1 are CIE 1931 (x, y) chromaticity coordinates for primaries of the DCI-P3 and Rec. 2020 colour gamut standards and for a commercial OLED display. Generally, for red light, a higher CIE x value corresponds to deeper emission, for green light, a higher CIE y value corresponds to deeper emission, and for blue light, a lower CIE y value corresponds to deeper emission. This can be understood with reference FIG. 7, which depicts red, green and blue data from Table 1 for light R&D OLEDs (squares), deep R&D OLEDs (triangles) and a Commercial OLED display (stars) as well as the primaries of the DCI-P3 colour gamut in FIG. 7a and the Rec. 2020 colour gamut in FIG. 7b.

TABLE 1
CIE 1931 (x, y) chromaticity coordinates for exemplary
light and deep OLEDs and for a Commercial OLED display.
Also included are chromaticity coordinates for primaries
of the DCI-P3 and Rec. 2020 colour gamuts.

| | | Red | | Green | | Blue | |
|---|---|---|---|---|---|---|---|
| | | CIE x | CIE y | CIE x | CIE y | CIE x | CIE y |
| DCI-P3 | | 0.680 | 0.320 | 0.265 | 0.690 | 0.150 | 0.060 |
| Rec. 2020 | | 0.708 | 0.292 | 0.170 | 0.797 | 0.131 | 0.046 |
| Commercial OLED | | 0.680 | 0.320 | 0.265 | 0.690 | 0.150 | 0.060 |
| Light | OLED | 0.620 | 0.370 | 0.441 | 0.548 | 0.170 | 0.380 |
| Deep | OLED | 0.709 | 0.290 | 0.180 | 0.740 | 0.146 | 0.045 |

The CIE 1931 (x, y) chromaticity coordinate data reported in Table 1 are exemplary. Commercial OLED data are taken from the Apple iphone 14 Pro Max, which fully supports the DCI-P3 colour gamut. This data set is available from Raymond Soneira at DisplayMate Technologies Corporation (Soneira et al.). The other data are taken from a selection of peer-reviewed scientific journals: Light red OLED data are taken from Jang et al. Light green OLED data are taken from Yu et al. Light blue OLED data are taken from Weaver et al. Deep red OLED data are taken from Hosoumi et al. Deep green OLED data are taken from Fukagawa et al. Deep-blue OLED data are taken from Takita et al. Data from these sources are used by way of example and should be considered non-limiting. Data from other peer-reviewed scientific journals, simulated data and/or experimental data collected from laboratory devices may also be used to demonstrate the aforementioned advantages of the claimed device architecture.

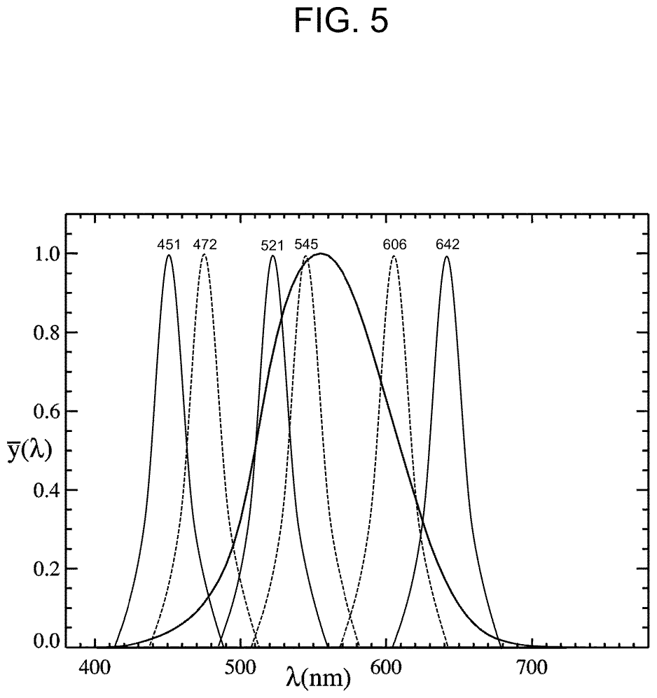

The presented chromaticity data can be further understood with reference to emission spectra. FIG. 5 depicts exemplary normalized electroluminescence emission spectra for the red, green and blue OLEDs summarized in Table 1. The spectra depicted using dashed lines correspond to spectra for OLEDs that emit light red, light green and light blue light with respective emission peaks at 606 nm, 545 nm and 472 nm. The spectra depicted using solid lines correspond to spectra for OLEDs that emit deep red, deep green and deep blue light with respective emission peaks at 642 nm, 521 nm and 451 nm. Note that the shapes of the emission spectra have been simplified to Gaussian curves for ease of understanding.

Exemplary data are shown for OLEDs in FIG. 5 and FIG. 7, but the same principles may also be applied to other LEDs, including QLEDs, PeLEDs and I-LEDs.

Emission spectra with peaks located closer to the peak of the photopic luminous efficiency function at approximately 555 nm to 557 nm generally have greater overlap with the photopic luminous efficiency function. FIG. 5 shows that the light red, light green and light blue emission spectra have greater overlap with the photopic luminous efficiency function than the respective deep red, deep green and deep blue emission spectra. This means that fewer photons are required for the same perceived brightness for light red, light green and light blue light than for deep red, deep green and deep blue light. Regions that emit light red, light green and light blue light may therefore have greater luminous efficiency than regions that emit deep red, deep green and deep blue light. The display of the present invention, comprising regions that emit light of the same hue but different chromaticity, may therefore operate with improved efficiency. This is because the more efficient lighter red, green and blue regions may be used to render the majority of images, with the less efficient deeper red, green and blue regions used only to render a minority of images where extended colour gamut is required.

In one embodiment, the regions that emit lighter red 915 or 1115, green 935 or 1135 and blue 955 or 1155 light may together render a first colour gamut; and the regions that emit deeper red 925 or 1125, green 945 or 1145 and blue 965 or 1165 light may together render a second colour gamut, wherein the first colour gamut is narrower than the second colour gamut.

For a display with a pixel arrangement such as depicted in FIG. 8, FIG. 9, FIG. 10 and FIG. 11, comprising: a first region 915 or 1115 that emits light red light; a second region 925 or 1125 that emits deep red light; a third region 935 or 1135 that emits light green light; a fourth region 945 or 1145 that emits deep green light; a fifth region 955 or 1155 that emits light blue light; and a sixth region 965 or 1165 that emits deep blue light, the lighter red, green and blue regions with greater overlap with the photopic luminous efficiency function and therefore higher efficiency may be used to render the majority of display images that require relatively less saturated pixel colours. The deeper red, green and blue regions with less overlap with the photopic luminous efficiency function and therefore lower efficiency are only used as needed to render images that require relatively more saturated colours, resulting in significant power savings for a display comprising such a pixel arrangement.

The power consumption of the disclosed display design can be computed and compared to a standard display design using linear additive display models and typical image colour distributions. For such displays, power consumption and power savings are dependent on the displayed imaged content, and on the efficacies and chromaticities of the LEDs of the deeper and lighter red, green and blue regions.

Table 2 lists exemplary luminous efficacy (cd/A), CIE 1931 (x, y) chromaticity coordinates and CIE 1976 (u′, v′) chromaticity coordinates for the deeper and lighter red, green and blue regions.

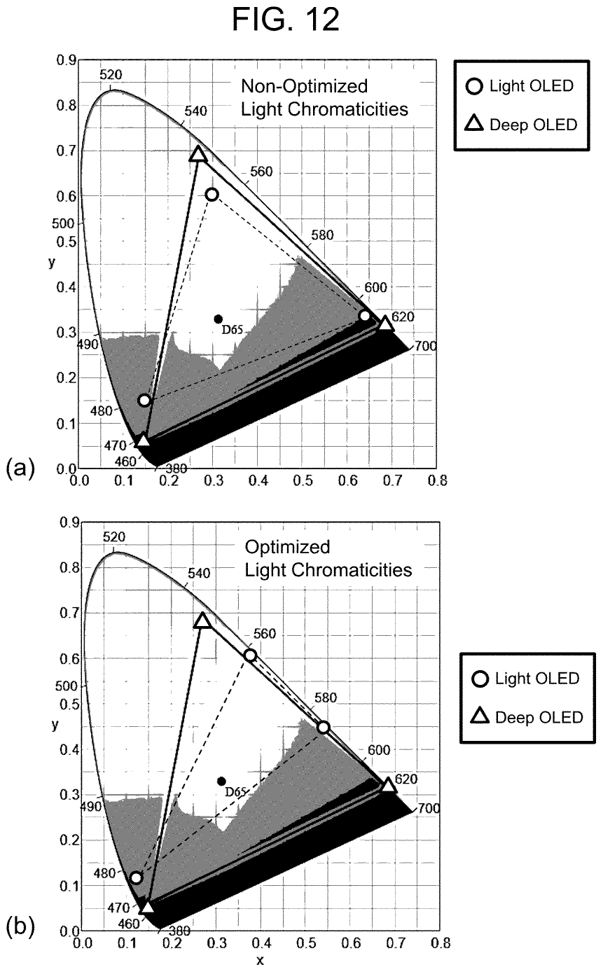

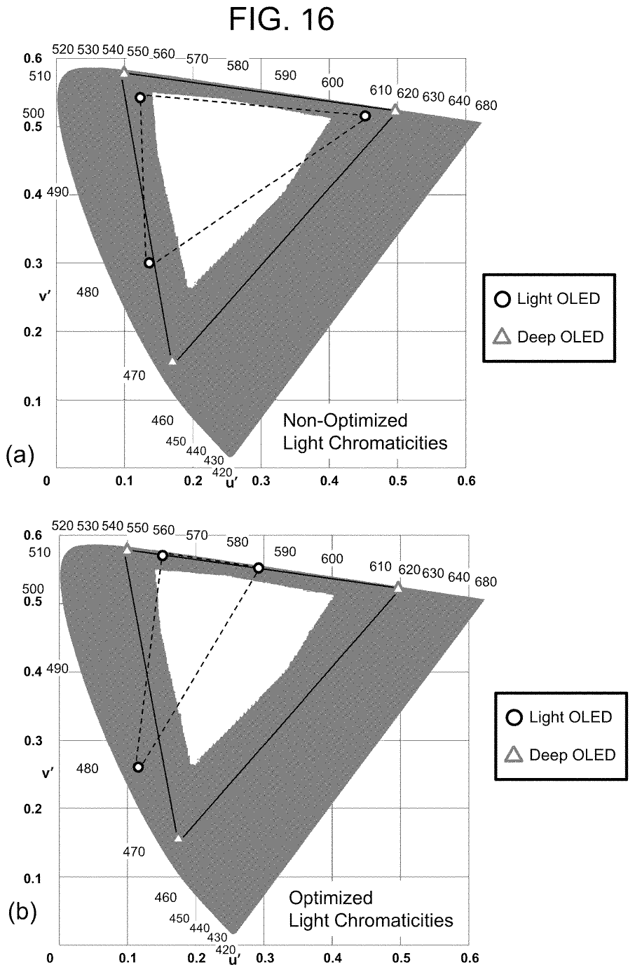

The CIE 1931 (x, y) chromaticity coordinates from Table 2 are also depicted in FIG. 12a in the CIE 1931 (x, y) chromaticity diagram. The CIE 1976 (u′, v′) chromaticity coordinates from Table 2 are also depicted in FIG. 16a in the CIE 1976 (u′ v′) chromaticity diagram. In FIG. 12a and FIG. 16a, lighter primary colours are depicted by circles and deeper primary colours are depicted by triangles with lines that show the respective red, green and blue colour gamuts that can be achieved with these primaries. The dashed lines correspond to the first colour gamut rendered by lighter red, green and blue primaries. The solid lines correspond to the second colour gamut rendered by the deeper red, green and blue primaries, which are the same as for the DCI-P3 colour gamut. The first colour gamut is narrower than the second colour gamut. In FIG. 12a, the area of the first colour gamut is 59.3% of the area of the second colour gamut in the CIE 1931 (x, y) chromaticity diagram. In FIG. 16a, the area of the first colour gamut is 52.5% of the area of the second colour gamut in the CIE 1976 (u′, v′) chromaticity diagram.

TABLE 2
Efficacy (cd/A) and CIE 1931 (x, y) and CIE 1976 (u′, v′) chromaticity
coordinates for exemplary non-optimized lighter and
deeper red, green and blue regions.

| | | Efficacy | | |
|---|---|---|---|---|
| Region | | (cd/A) | CIE 1931 (x, y) | CIE 1976 (u′, v′) |
| Lighter | Red | 90 | (0.640, 0.330) | (0.451, 0.523) |
| Non- | Green | 200 | (0.300, 0.600) | (0.125, 0.563) |
| Optimized | Blue | 40 | (0.150, 0.150) | (0.133, 0.300) |
| Deeper | Red | 60 | (0.680, 0.320) | (0.496, 0.526) |
| | Green | 160 | (0.265, 0.690) | (0.099, 0.578) |
| | Blue | 12 | (0.150, 0.060) | (0.175, 0.158) |

Reproduced from EP 21740183.5.

The exemplary luminous efficacy and chromaticity coordinates disclosed in Table 2 have been taken from European patent application EP 21740183.5. The chromaticities of the deeper red, green and blue regions are the same as the DCI-P3 primaries, and the efficacies of the deeper red, green and blue regions have been estimated from commercial OLED devices. The chromaticities of the lighter red and green regions are the same as the primaries of the sRGB colour gamut. The chromaticity of the lighter blue region is taken to be CIE 1931 (x, y)=(0.15, 0.15) to ensure a greater overlap with the photopic luminous efficiency function. The efficacies of the lighter red, green and blue regions have been calculated by assuming the same external quantum efficiency as for the respective deeper red, green and blue regions and then scaling the efficacies according to the increased overlap with the photopic luminous efficiency function of the lighter colours as calculated by the Luminous Efficacy of Radiation (LER).

The chromaticities and efficacies in Table 2 were used to compute display power consumption for (a) a Uniform Colour Distribution (meaning every colour in the DCI-P3 colour gamut is equally likely on the display) and (b) an Average Colour Distribution (meaning that the likelihood of any particular colour is taken from average observed image statistics for a display, which more heavily weights less saturated colours). Power consumption was computed for the herein disclosed display architecture with lighter red, green and blue and deeper red, green and blue regions, as well as for a reference display comprising only equivalent deeper red, green and blue regions. The chromaticities for lighter red, green and blue were taken from EP 21740183.5 and have not been optimized. The results are disclosed in Table 3 as “Deep Only” and “Deep and Light Regions, Non-Optimized Light Chromaticities”.

An additive colour model was assumed, which is typical for contemporary OLED displays. It was assumed that the chromaticity of each region is independent of luminance and that the light emission from each region is independent of the light emission from the other regions in the display.

TABLE 3
Relative power consumption (arbitrary units) for different
image distributions for different display architectures.

| | Power Savings | |
|---|---|---|
| | Uniform Colour | Average Colour |
| Regions | Distribution | Distribution |
| Deep Only | 0% | 0% |
| Deep and Light Regions Non- | 19.8% | 24.3% |
| Optimized Light Chromaticities | | |
| Deep and Light Regions | 21.3% | 27.2% |
| Optimized Light Chromaticities | | |

For a uniform colour distribution, an OLED display comprising deeper and lighter red, green and blue regions (where the chromaticities of the lighter red, green and blue regions are non-optimized as in EP21740183.5) consumes 19.8% less power than a reference OLED display comprising only deeper red, green and blue regions. Power savings are 24.3% for an average colour distribution. For other distributions of colour, the results are expected to vary slightly, but are expected to remain in this range.

The calculated power savings are substantial. However, the present invention is different from and provides significant benefits compared to the related display design disclosed in EP 21740183.5. The present invention improves on EP 21740183.5 because chromaticity and emission wavelengths of light emitted from the regions that emit lighter red 915 or 1115, green 935 or 1135, and blue 955 or 1155 light that together render the first colour gamut are herein optimized to minimize display power consumption, unlike in EP 21740183.5, where the chromaticities of the lighter red and green regions are arbitrarily set without optimization to be the same as the primaries of the sRGB colour gamut and the chromaticity of the lighter blue region is arbitrarily set without optimization to be CIE 1931 (x, y)=(0.15, 0.15).

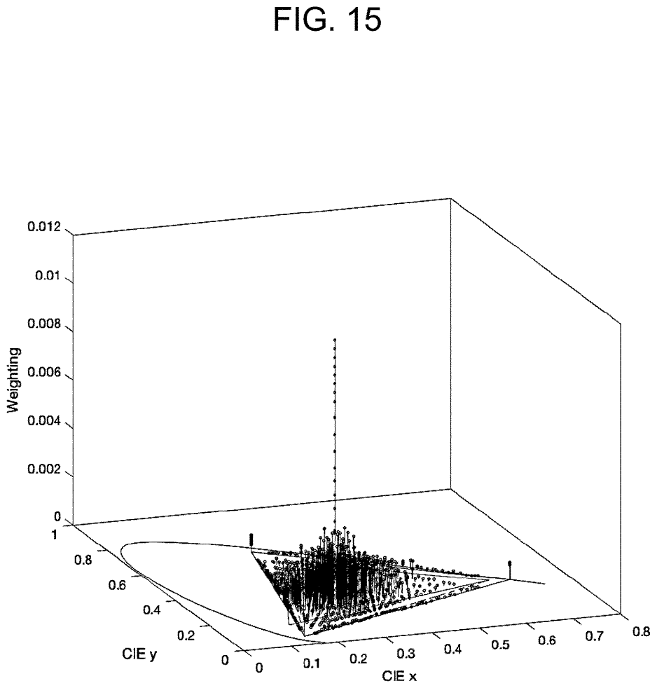

In the present invention, to identify the optimized chromaticities of the lighter red 915 or 1115, green 935 or 1135, and blue 955 or 1155 regions, the distribution of colours in a series of typical display images was calculated. FIG. 15 depicts the distribution of image chromaticity for a series of typical images in the 1931 CIE (x, y) chromaticity diagram. The height of the dots above the x-y plane indicates the relative weighting of colours in typical images. The high peak at the centre corresponds to the D65 white point, with a smooth fall toward the edges of the colour gamut. The small peaks at each of the corners of the gamut correspond to the intermediate likelihood of pure red, green, and blue colours, as often used in graphic design. Furthermore, two triangles are depicted in the x-y plane. The larger triangle corresponds to the DCI-P3 colour gamut for deeper red, green and blue, whereas the smaller triangle corresponds to the arbitrary colour gamut reported in EP 21740183.5 for lighter red, green and blue.

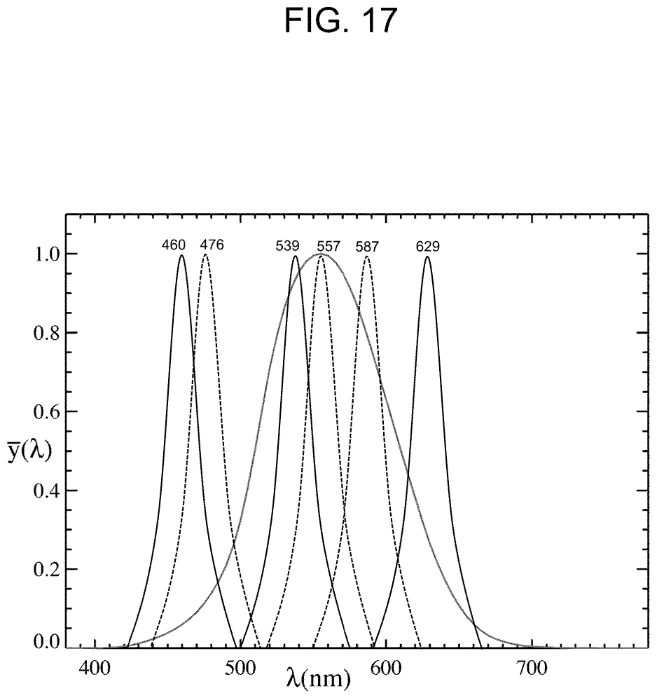

FIG. 15 confirms that the arbitrary colour gamut reported in EP 21740183.5 for the lighter red, green and blue is wider than optimal and that the majority of typical image chromaticities are contained in a narrower gamut centralized on the D65 white point. Using the chromaticity distribution data depicted in FIG. 15, the optimized chromaticities for the lighter red 915 or 1115, green 935 or 1135, and blue 955 or 1155 regions were calculated. The data is summarized in Table 4 and depicted in FIG. 12b, FIG. 16b and FIG. 17. The chromaticity coordinates are given in the CIE 1931 (x, y) chromaticity diagram and in the CIE 1976 (u′, v′) chromaticity diagram. Also summarized in Table 4 are the peak wavelength and frequency width at half maximum (FWHM) for each region.

The chromaticities of the deeper red, green and blue regions are the same as the DCI-P3 primaries, and the efficacies of the deeper red, green and blue regions have been estimated from commercial OLED devices. The chromaticities of the lighter red, green and blue regions have been optimized so as to maximize power savings of a display when rendering typical images. The efficacies of the lighter red, green and blue regions have been calculated by assuming the same external quantum efficiency as for the respective deeper red, green and blue regions and then scaling the efficacies according to the increased overlap with the photopic luminous efficiency function of the lighter colours as calculated by the Luminous Efficacy of Radiation (LER).

TABLE 4
Efficacy (cd/A), CIE 1931 (x, y) and CIE 1976 (u′, v′) chromaticity
coordinates, peak emission wavelength and FWHM for optimized
lighter and deeper red, green and blue regions.

| | | Efficacy | | | Peak | FWHM |
|---|---|---|---|---|---|---|
| Region | | (cd/A) | CIE 1931 (x, y) | CIE 1976 (u′, v′) | (nm) | (nm) |
| Lighter | Red | 145 | (0.536, 0.463) | (0.286, 0.557) | 587 | 50 |
| | Green | 172 | (0.374, 0.614) | (0.156, 0.574) | 557 | 50 |
| | Blue | 43 | (0.118, 0.129) | (0.109, 0.269) | 476 | 50 |
| Deeper | Red | 60 | (0.680, 0.320) | (0.496, 0.526) | 629 | 43 |
| | Green | 160 | (0.265, 0.690) | (0.099, 0.578) | 539 | 50 |
| | Blue | 12 | (0.150, 0.060) | (0.175, 0.158) | 460 | 54 |

The CIE 1931 (x, y) chromaticity coordinates from Table 4 are depicted in FIG. 12b in the CIE 1931 (x, y) chromaticity diagram. The CIE 1976 (u′, v′) chromaticity coordinates from Table 4 are depicted in FIG. 16b in the CIE 1976 (u′ v′) chromaticity diagram. In FIG. 12b and FIG. 16b, lighter primary colours are depicted by circles and deeper primary colours are depicted by triangles with lines that show the respective red, green and blue colour gamuts that can be achieved with these primaries. The dashed lines correspond to the first colour gamut rendered by lighter red, green and blue primaries. The solid lines correspond to the second colour gamut rendered by the deeper red, green and blue primaries, which are the same as for the DCI-P3 colour gamut. The first colour gamut is narrower than the second colour gamut. In FIG. 12b, the area of the first colour gamut is 35.9% of the area of the second colour gamut in the CIE 1931 (x, y) chromaticity diagram. In FIG. 16b, the area of the first colour gamut is 24.8% of the area of the second colour gamut in the CIE 1976 (u′, v′) chromaticity diagram.

FIG. 17 depicts emission spectra for the light red, deep red, light green, deep green, light blue and deep blue regions summarized in Table 4, with peak wavelengths at 587 nm, 629 nm, 557 nm, 539 nm, 476 nm and 460 nm. Note that the shapes of the emission spectra have been simplified to Gaussian curves for ease of understanding, with 50 nm FWHM for light red, green and blue, 43 nm FWHM for deep red, 50 nm FWHM for deep green and 54 nm FWHM for deep blue. Note that the spectral shapes depicted in FIG. 17 are exemplary, and similar chromaticities as summarized in Table 4 could be achieved using emission spectra with alternative peak wavelengths and FWHMs.

In one embodiment, any or all of the emission spectra for the light and deep red, green and blue regions may have FWHM of less than 50 nm. In one embodiment, any or all of the emission spectra for the light and deep red, green and blue regions may have FWHM of less than 30 nm. In one embodiment, any or all of the emission spectra for the light and deep red, green and blue regions may have FWHM in the range of 15 nm to 30 nm. As described herein, such narrower emission spectra with such FWHM may be achieved using microcavity structures. The peak wavelengths of the emission spectra may then be adjusted so that the light and deep red, green and blue regions may emit light with the approximate optimized chromaticities summarized in Table 4.

Compared to the exemplary (non-optimized) emission spectra for light red, green and blue depicted in FIG. 5 with peak wavelengths at 606 nm, 545 nm and 472 nm, respectively, the overlap of the emission spectra with the photopic luminous efficiency function for optimized light red, green and blue regions with peak wavelengths at 587 nm, 557 nm and 476 nm, respectively, in FIG. 17 is substantially greater. This results in higher luminous efficiency and reduced display power consumption for the optimized lighter red, green and blue regions as disclosed herein. In particular, the peak wavelength of the light green emission spectrum has been optimized to 557 nm to align to the peak of the photopic luminous efficiency function to ensure maximum luminous efficiency for the light green region.

The chromaticities and efficacies in Table 4 were used to compute display power consumption for (a) a Uniform Colour Distribution) and (b) an Average Colour Distribution. Power consumption was computed for the herein disclosed display architecture with lighter red, green and blue and deeper red, green and blue regions, where the lighter red, green and blue chromaticities have been optimized, as well as for a reference display comprising only equivalent deeper red, green and blue regions. The results are disclosed in Table 4 as “Deep Only” and “Deep and Light Regions, Optimized Light Chromaticities”.

Once again, an additive colour model was assumed, which is typical for contemporary OLED displays. It was assumed that the chromaticity of each region is independent of luminance and that the light emission from each region is independent of the light emission from the other regions in the display.

For a uniform colour distribution, an OLED display comprising deeper and lighter red, green and blue regions (where the chromaticities of the lighter red, green and blue regions are optimized as disclosed herein) consumes 21.3% less power than a reference OLED display comprising only deeper red, green and blue regions. Power savings are 27.2% for an average colour distribution. For other distributions of colour, the results are expected to vary slightly, but are expected to remain in this range.

The data in Table 4 confirm that by aligning the peak wavelength of the emission spectrum of the light green region to the peak of the photopic luminous efficiency function at 555 nm to 557 nm, and by optimizing the chromaticities of light red and blue regions to maximize overlap of their emission spectra with the photopic luminous efficiency function, while ensuring that the majority of typical image chromaticities can still be rendered by the first colour gamut of light red, green and blue, substantial display power savings can be achieved.

In particular, by reducing the area of the first colour gamut from 59.2% to 35.9% of the area of the second colour gamut in the CIE 1931 (x, y) chromaticity diagram, and from 52.5% to 24.8% of the area of the second colour gamut in the CIE 1976 (u′, v′) chromaticity diagram, display power savings can be increased from 24.3% to 27.2% for an average colour distribution.

The present invention is also different from and provides significant benefits compared to a related display design disclosed in United States patent U.S. Pat. No. 9,559,151 B2. U.S. Pat. No. 9,559,151 B2 discloses a device that may be used as a multi-colour pixel, wherein the device comprises a first OLED, a second OLED, a third OLED and a fourth OLED. The device may be a pixel of a display having four sub-pixels, wherein the first sub-pixel comprises an OLED that may emit red light, the second sub-pixel comprises an OLED that may emit green light, the third sub-pixel comprises an OLED then may emit light-blue light, and the fourth sub-pixel comprises an OLED that may emit deep-blue light.

The present invention improves on U.S. Pat. No. 9,559,151 B2 because significant power savings are also possible for red and green, and not just for blue. Furthermore, unlike U.S. Pat. No. 9,559,151 B2, the present invention enables the colour gamut of the display to be significantly expanded.

The herein disclosed display design has the potential to substantially reduce the power consumption of displays to the benefit of the environment, without compromising colour gamut. For portable electronic devices, such as smartphones, tablets, laptops and smartwatches, the herein disclosed display design also has the potential to extend the daily battery life of the device because of the lower power consumption of the display.

In one embodiment, the herein disclosed display design may also be used to extend the colour gamut of a display without increasing power consumption beyond that of the reference OLED display. In one embodiment, the deeper red, green and blue regions may emit light that is deeper in colour than the DCI-P3 colour gamut. In one embodiment, the deeper red, green and blue regions may emit light that enables the display to render the Rec. 2020 colour gamut. Although these deeper red, green and blue regions may be less efficient and consume more power than the regions of the reference OLED display, the power savings from the use of the more efficient lighter red, green and blue regions may offset this and enable the display to render a broader colour gamut, such as the Rec. 2020 colour gamut, without increasing the power consumption of the display beyond that of the reference OLED display. Alternatively, the brightness of the display may be increased without increasing the power consumption of the display beyond that of the reference OLED display. In one embodiment, any or all of these benefits may be achieved in the same device, and the power consumption of the display may be reduced, the brightness increased and the colour gamut of the display extended.

In one embodiment, the area of the first colour gamut is less than 55% of the area of the second colour gamut in the CIE 1931 (x, y) chromaticity diagram. In one embodiment, the area of the first colour gamut is less than 45% of the area of the second colour gamut in the CIE 1931 (x, y) chromaticity diagram. Such embodiments may be achieved using the chromaticities of the optimized red, green and blue regions summarized in Table 4. In one embodiment, the area of the first colour gamut is less than 35% of the area of the second colour gamut in the CIE 1931 (x, y) chromaticity diagram. Such an embodiment may be achieved by slightly tuning the chromaticities of the optimized red, green and blue regions summarized in Table 4. By minimizing the area of the first colour gamut around the D65 white point, the light red, green and blue emission spectra may have greater overlap with the photopic luminous efficiency function and therefore may emit light with greater luminous efficiency, leading to reduced display power consumption.

One limitation of using the CIE 1931 (x, y) chromaticity diagram to quantify and compare colour gamuts is that distance is not proportional to perceived difference in colour in the CIE 1931 (x, y) chromaticity diagram. When quantifying and comparing colour gamuts it is preferable to use the CIE 1976 (u′, v′) chromaticity diagram because unlike the CIE 1931 (x, y) chromaticity diagram, in the CIE 1976 (u′, v′) chromaticity diagram, distance is approximately proportional to perceived difference in colour. The area of a colour gamut in the CIE 1976 (u, v′) chromaticity is therefore approximately proportional to the number of distinguishable colours that may be rendered by the colour gamut.

In one embodiment, the area of the first colour gamut is less than 50% of the area of the second colour gamut in the CIE 1976 (u′, v′) chromaticity diagram. In one embodiment, the area of the first colour gamut is less than 40% of the area of the second colour gamut in the CIE 1976 (u′, v′) chromaticity diagram. In one embodiment, the area of the first colour gamut is less than 25% of the area of the second colour gamut in the CIE 1976 (u′, v′) chromaticity diagram. Such embodiments may be achieved using the chromaticities of the optimized red, green and blue regions summarized in Table 4.

In one embodiment, the first region 915 or 1115 may emit lighter red light and the second region 925 or 1125 may emit deeper red light. In one embodiment, the third region 935 or 1135 may emit lighter green light and the fourth region 945 or 1145 may emit deeper green light. In one embodiment, the fifth region 955 or 1155 may emit lighter blue light and the sixth region 965 or 1165 may emit deeper blue light.

In one embodiment, the first region 915 or 1115 and the second region 925 or 1125 may both emit red light with a peak wavelength in the range of 580 nm to 780 nm. In one embodiment, the third region 935 or 1135 and the fourth region 945 or 1145 may both emit green light with a peak wavelength in the range of 500 nm to 580 nm. In one embodiment, the fifth region 955 or 1155 and the sixth region 965 or 1165 may both emit blue light with a peak wavelength in the range of 380 nm to 500 nm. Such embodiments may be achieved using the chromaticities of the optimized red, green and blue regions summarized in Table 4.

In one embodiment, the first region 915 or 1115 may emit red light with a peak wavelength in the range of 580 nm to 610 nm and the second region 925 or 1125 may emit red light with a peak wavelength in the range of 610 nm to 780 nm. In one embodiment, the third region 935 or 1135 may emit green light with a peak wavelength in the range of 540 nm to 580 nm; and the fourth region 945 or 1145 may emit green light with a peak wavelength in the range of 500 nm to 540 nm. In one embodiment, the fifth region 955 or 1155 may emit blue light with a peak wavelength in the range of 470 nm to 500 nm; and the sixth region 965 or 1165 may emit blue light with a peak wavelength in the range of 380 nm to 470 nm. Such embodiments may be achieved using the chromaticities of the optimized red, green and blue regions summarized in Table 4.

In one embodiment, the third region 935 or 1135 may emit green light with a peak wavelength in the range of 550 nm to 560 nm. In one embodiment, the third region 935 or 1135 may emit green light with a peak wavelength in the range of 555 nm to 557 nm.

This may be advantageous because the overlap of the emission spectrum of green light emitted from the third region and the photopic luminous efficiency function may be maximized. Such embodiments may be achieved using the chromaticities of the optimized red, green and blue regions summarized in Table 4.

In one embodiment, the first region 915 or 1115 may emit red light with a peak wavelength in the range of 580 nm to 600 nm. In one embodiment, the third region 935 or 1135 may emit green light with a peak wavelength in the range of 550 nm to 560 nm, In one embodiment, the fifth region 955 or 1155 may emit blue light with a peak wavelength in the range of 465 nm to 485 nm. Such embodiments may be achieved using the chromaticities of the optimized red, green and blue regions summarized in Table 4.

In one embodiment, the first region 915 or 1115 may emit red light with a peak wavelength in the range of 585 nm to 595 nm. In one embodiment, the third region 935 or 1135 may emit green light with a peak wavelength in the range of 550 nm to 560 nm, In one embodiment, the fifth region 955 or 1155 may emit blue light with a peak wavelength in the range of 470 nm to 480 nm. Such embodiments may be achieved using the chromaticities of the optimized red, green and blue regions summarized in Table 4.

In one embodiment, the first region 915 or 1115 may emit red light with a CIE 1931 x coordinate of less than 0.640 and the second region 925 or 1125 may emit red light with a CIE 1931 x coordinate of 0.640 or more. In one embodiment, the third region 935 or 1135 may emit green light with a CIE 1931 y coordinate of less than 0.650 and the fourth region 945 or 1145 may emit green light with a CIE 1931 y coordinate of 0.650 or more. In one embodiment, the fifth region 955 or 1155 may emit blue light with a CIE 1931 y coordinate of more than 0.080 and the sixth region 965 or 1165 may emit blue light with a CIE 1931 y coordinate of 0.080 or less. Such embodiments may be achieved using the chromaticities of the optimized red, green and blue regions summarized in Table 4.

In one embodiment, the first region 915 or 1115 may emit red light with CIE 1931 x coordinate in the range of 0.500 to 0.575 and CIE 1931 y coordinate in the range of 0.425 to 0.500. In one embodiment, the third region 935 or 1135 may emit green light with CIE 1931 x coordinate in the range of 0.335 to 0.415 and CIE 1931 y coordinate in the range of 0.575 to 0.649. In one embodiment, the fifth region 955 or 1155 may emit blue light with CIE 1931 x coordinate in the range of 0.075 to 0.155 and CIE 1931 y coordinate in the range of 0.081 to 0.245.

These ranges of CIE 1931 x and CIE 1931 y coordinates for light red, light green and light blue are preferred because they reduce display power consumption for a typical distribution of display images. This can be understood with reference to FIG. 15 which depicts the distribution of image chromaticity in the 1931 CIE (x, y) chromaticity diagram for 1400 typical display images. It can be seen that the majority of image chromaticities may be enclosed within a first colour gamut defined by a first region 915 or 1115 that emits red light with CIE 1931 x coordinate in the range of 0.500 to 0.575 and CIE 1931 y coordinate in the range of 0.425 to 0.500; a third region 935 or 1135 that emits green light with CIE 1931 x coordinate in the range of 0.335 to 0.415 and CIE 1931 y coordinate in the range of 0.575 to 0.649; and a fifth region 955 or 1155 that emits blue light with CIE 1931 x coordinate in the range of 0.075 to 0.155 and CIE 1931 y coordinate in the range of 0.081 to 0.245.

In particular, it is preferred that the fifth region 955 or 1155 emits blue light with CIE 1931 x coordinate in the range of 0.075 to 0.155 and CIE 1931 y coordinate in the range of 0.081 to 0.245. This range of chromaticities enables the more efficient light blue of the fifth region 955 or 1155 to render the majority of images and for the less efficient deep blue of the sixth region 965 or 1165 to be only used to render a minority of images where saturated blue is needed. This reduces display power consumption. This range of chromaticities for the light blue of the fifth region 955 or 1155 is a substantial improvement over the previous work reported in United States patent U.S. Pat. No. 7,982,385 B2, where a light blue region having CIE 1931 (x, y) chromaticity coordinates (0.180, 0.320) is reported, and a substantial improvement over the previous work reported in WIPO (PCT) patent application WO 2022/003352 A1, where a light blue region having CIE 1931 (x, y) chromaticity coordinates (0.140, 0.290) is reported. Both of these previously reported chromaticities for the light blue of the fifth region 955 or 1155 are too light to minimize display power consumption. The less efficient deep blue of the sixth region 965 or 1165 would need to be used to render a greater number of typical images and this would increase display power consumption relative to the chromaticity range for the light blue of the fifth region 955 or 1155 reported in the present work.

In one embodiment, the first region 915 or 1115 may emit red light with CIE 1931 x coordinate in the range of 0.515 to 0.560 and CIE 1931 y coordinate in the range of 0.440 to 0.485. In one embodiment, the third region 935 or 1135 may emit green light with CIE 1931 x coordinate in the range of 0.355 to 0.395 and CIE 1931 y coordinate in the range of 0.595 to 0.635. In one embodiment, the fifth region 955 or 1155 may emit blue light with CIE 1931 x coordinate in the range of 0.100 to 0.140 and CIE 1931 y coordinate in the range of 0.110 to 0.150.

These ranges of CIE 1931 x and CIE 1931 y coordinates for light red, light green and light blue are more preferred because they further reduce display power consumption for a typical distribution of display images.

In one embodiment, the second colour gamut is the DCI-P3 colour gamut.

In one embodiment, the second colour gamut is the Rec. 2020 colour gamut.

In one embodiment, the first colour gamut and the second colour gamut both enclose the D65 white point. This is preferred because as depicted in FIG. 15, the D65 white point, which has CIE 1931 (x, y) chromaticity coordinates of (0.313, 0329), and the colours with chromaticities near to the D65 white point are by far the most common colours rendered on a display. FIG. 12b depicts the first colour gamut and the second colour gamut both enclosing the D65 white point. The lighter red, green and blue regions of the first colour gamut with higher efficiency may be used to render the majority of display images that require relatively less saturated pixel colours. The deeper red, green and blue regions of the second colour gamut with lower efficiency are then only used as needed to render images that require relatively more saturated colours, resulting in significant power savings for a display comprising such a pixel arrangement.

The present work is a substantial improvement over previous work reported in United States patent U.S. Pat. No. 7,982,385 B2, where a pixel arrangement comprising two red (R1 and R2), two green (G1 and G2) and two blue sub-pixels (B1 and B2) is reported. The focus of this work was on increasing display colour gamut rather than reducing display power consumption, so exemplary emission spectra for R1 and R2 (see FIG. 8), G1 and G2 (see FIG. 9) and B1 and B2 (see FIG. 10) were selected with the following CIE 1931 (x, y) chromaticity coordinates: R1 (0.68, 0.32), R2 (0.47, 0.52), G1 (0.28, 0.63), G2 (0.43, 0.56), B1 (0.15, 0.11) and B2 (0.18, 0.32). Unfortunately, as depicted in FIG. 11, the resulting colour gamut RGB2 using the more efficient lighter colours does not then enclose the D65 white point. It is therefore impossible for the more efficient lighter sub-pixels R2, G2 and B2 to be used to render the majority of display images. The pixel arrangement reported in U.S. Pat. No. 7,982,385 B2 is therefore not effective at reducing display power consumption.

In one embodiment, any of the first 915 or 1115, second 925 or 1125, third 935 or 1135, fourth 945 or 1145, fifth 955 or 1155 and sixth 965 or 1165 regions may comprise one and not more than one emissive layer. Such architectures may be advantageous because they may simplify the production process. In one embodiment, any of the first 915 or 1115, second 925 or 1125, third 935 or 1135, fourth 945 or 1145, fifth 955 or 1155 and sixth 965 or 1165 regions may comprise two or more emissive layers. Such architectures may be advantageous because light from multiple emissive layers may be combined to achieve a desired brightness and/or chromaticity.

In one embodiment, any of the first 915 or 1115, second 925 or 1125, third 935 or 1135, fourth 945 or 1145, fifth 955 or 1155 and sixth 965 or 1165 regions may comprise one and not more than one emissive unit. Such architectures may be advantageous because they may simplify the production process. In one embodiment, any of the first 915 or 1115, second 925 or 1125, third 935 or 1135, fourth 945 or 1145, fifth 955 or 1155 and sixth 965 or 1165 regions may comprise a stacked LED with two or more emissive units. Such architectures may be advantageous because light from multiple emissive units may be combined to achieve a desired brightness and/or chromaticity.

In one embodiment, any of the first 915 or 1115, second 925 or 1125, third 935 or 1135, fourth 945 or 1145, fifth 955 or 1155 and sixth 965 or 1165 regions comprise LEDs. In one embodiment, any of the first 915 or 1115, second 925 or 1125, third 935 or 1135, fourth 945 or 1145, fifth 955 or 1155 and sixth 965 or 1165 regions comprise OLEDs. In one embodiment, any of the first 915 or 1115, second 925 or 1125, third 935 or 1135, fourth 945 or 1145, fifth 955 or 1155 and sixth 965 or 1165 regions comprise I-LEDs. In one embodiment, any of the first 915 or 1115, second 925 or 1125, third 935 or 1135, fourth 945 or 1145, fifth 955 or 1155 and sixth 965 or 1165 regions comprise QLEDs. In one embodiment, any of the first 915 or 1115, second 925 or 1125, third 935 or 1135, fourth 945 or 1145, fifth 955 or 1155 and sixth 965 or 1165 regions comprise PeLEDs. In one embodiment, the first 915 or 1115, second 925 or 1125, third 935 or 1135, fourth 945 or 1145, fifth 955 or 1155 and sixth 965 or 1165 regions may comprise a combination of OLEDs, QLEDs, PeLEDs and I-LEDs in the same display.

In one embodiment, all of the first 915 or 1115, second 925 or 1125, third 935 or 1135, fourth 945 or 1145, fifth 955 or 1155 and sixth 965 or 1165 regions comprise LEDs. In one embodiment, all of the first 915 or 1115, second 925 or 1125, third 935 or 1135, fourth 945 or 1145, fifth 955 or 1155 and sixth 965 or 1165 regions comprise OLEDs. In one embodiment, all of the first 915 or 1115, second 925 or 1125, third 935 or 1135, fourth 945 or 1145, fifth 955 or 1155 and sixth 965 or 1165 regions comprise I-LEDs. In one embodiment, all of the first 915 or 1115, second 925 or 1125, third 935 or 1135, fourth 945 or 1145, fifth 955 or 1155 and sixth 965 or 1165 regions comprise QLEDs. In one embodiment, all of the first 915 or 1115, second 925 or 1125, third 935 or 1135, fourth 945 or 1145, fifth 955 or 1155 and sixth 965 or 1165 regions comprise PeLEDs.

In one embodiment, any of the first 915 or 1115, second 925 or 1125, third 935 or 1135, fourth 945 or 1145, fifth 955 or 1155 and sixth 965 or 1165 regions MiniLEDs, MicroLEDs or NanoLEDs. In one embodiment, all of the first 915 or 1115, second 925 or 1125, third 935 or 1135, fourth 945 or 1145, fifth 955 or 1155 and sixth 965 or 1165 regions comprise MiniLEDs, MicroLEDs or NanoLEDs.

In one embodiment, as depicted in FIG. 8 and FIG. 9, the first region 915 comprises a first sub-pixel 810 that comprises a first LED that is configured to emit red light of the first chromaticity; the second region 925 comprises a second sub-pixel 820 that comprises a second LED that is configured to emit red light of the second chromaticity; the third region 935 comprises a third sub-pixel 830 that comprises a third LED that is configured to emit green light of the third chromaticity; the fourth region 945 comprises a fourth sub-pixel 840 that comprises a fourth LED that is configured to emit green light of the fourth chromaticity; the fifth region 955 comprises a fifth sub-pixel 850 that comprises a fifth LED that is configured to emit blue light of the fifth chromaticity; and the sixth region 965 comprises a sixth sub-pixel 860 that comprises a sixth LED that is configured to emit blue light of the sixth chromaticity; wherein each of the first, second, third, fourth, fifth and sixth LEDs comprise: a first electrode 970; a second electrode 980; and an emissive layer 910, 920, 930, 940, 950 or 960; wherein the emissive layer 910, 920, 930, 940, 950 or 960 is disposed over the first electrode 970; the second electrode 980 is disposed over the emissive layer 910, 920, 930, 940, 950 or 960; and none of the first, second, third, fourth, fifth or sixth LEDs are disposed over each other.

In one embodiment, as depicted in FIG. 10 and FIG. 11, the first region 1115 comprises a first emissive unit that is configured to emit red light of the first chromaticity; the second region 1125 comprises a second emissive unit that is configured to emit red light of the second chromaticity; the third region 1135 comprises a third emissive unit that is configured to emit green light of the third chromaticity; the fourth region 1145 comprises a fourth emissive unit that is configured to emit green light of the fourth chromaticity; the fifth region 1155 comprises a fifth emissive unit that is configured to emit blue light of the fifth chromaticity; and the sixth region 1165 comprises a sixth emissive unit that is configured to emit blue light of the sixth chromaticity; wherein a first sub-pixel 1010 comprises a first stacked LED comprising the first 1115 and second 1125 emissive units; a second sub-pixel 1020 comprises a second stacked LED comprising the third 1135 and fourth 1145 emissive units; and a third sub-pixel 1030 comprises a third stacked LED comprising the fifth 1155 and sixth 1165 emissive units; wherein the first stacked LED comprises: a first electrode 970; a second electrode 980; the first emissive unit 1115 comprising a first emissive layer; the second emissive unit 1125 comprising a second emissive layer; and a charge generation layer 1140; wherein the first emissive unit 1115, the second emissive unit 1125 and the charge generation layer 1140 are all disposed between the first electrode 970 and the second electrode 980; the first emissive unit 1115 is disposed over the second emissive unit 1125, or vice versa; the first emissive unit 1115 and the second emissive unit 1125 are separated by the charge generation layer 1140; and the first emissive unit 1115 and the second emissive unit 1125 are independently addressed and may emit light independently of each other; the second stacked LED comprises: a first electrode 970; a second electrode 980; the third emissive unit 1135 comprising a third emissive layer; the fourth emissive unit 1145 comprising a fourth emissive layer; and a charge generation layer 1140; wherein the third emissive unit 1135, the fourth emissive unit 1145 and the charge generation layer 1140 are all disposed between the first electrode 970 and the second electrode 980; the third emissive unit 1135 is disposed over the fourth emissive unit 1145, or vice versa; the third emissive unit 1135 and the fourth emissive unit 1145 are separated by the charge generation layer 1140; and the third emissive unit 1135 and the fourth emissive unit 1145 are independently addressed and may emit light independently of each other; and a third stacked LED comprises: a first electrode 970; a second electrode 980; the fifth emissive unit 1155 comprising a fifth emissive layer; the sixth emissive unit 1165 comprising a sixth emissive layer; and a charge generation layer 1140; wherein the fifth emissive unit 1155, the sixth emissive unit 1165 and the charge generation layer 1140 are all disposed between the first electrode 970 and the second electrode 980; the fifth emissive unit 1155 is disposed over the sixth emissive unit 1165, or vice versa; the fifth emissive unit 1155 and the sixth emissive unit 1165 are separated by the charge generation layer 1140; and the fifth emissive unit 1155 and the sixth emissive unit 1165 are independently addressed and may emit light independently of each other.

FIG. 11 depicts the second emissive unit 1125 disposed over the first emissive unit 1115, the fourth emissive unit 1145 disposed over the third emissive unit 1135 and the sixth emissive unit 1165 disposed over the fifth emissive unit 1155. However, the first emissive unit 1115 may also be disposed over the second emissive unit 1125, the third emissive unit 1135 may also be disposed over the fourth emissive unit 1145 and the fifth emissive unit 1155 may also be disposed over the sixth emissive unit 1165.

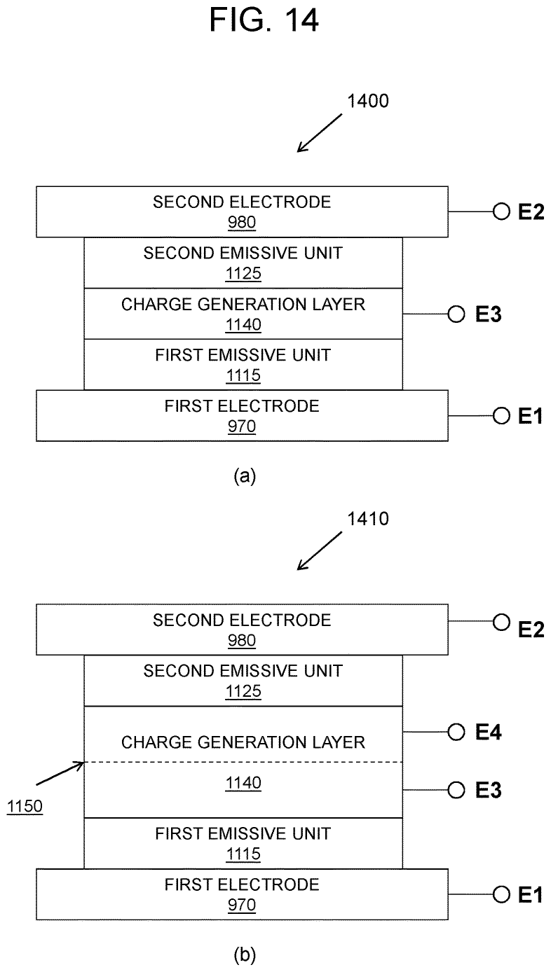

The first 1115 and second 1125 emissive units, third 1135 and fourth 1145 emissive units, and fifth 1115 and sixth 1165 emissive units may be independently addressed and may emit light independently of each other, as depicted in FIG. 14. FIG. 14 depicts exemplary architectures for the first 1115 and second 1125 emissive units. It should be understood that the positions of the first 1115 and second 1125 emissive units may be interchanged. It should also be understood that equivalent architectures may be used for the independently addressed third 1135 and fourth 1145 emissive units (with the third emissive unit 1135 taking the place of the first emissive unit 1115, and the fourth emissive unit 1145 taking the place of the second emissive unit 1125), and fifth 1155 and sixth 1165 emissive units (with the fifth emissive unit 1155 taking the place of the first emissive unit 1115, and the sixth emissive unit 1165 taking the place of the second emissive unit 1125), and that the positions of the third 1135 and fourth 1145 emissive units, and fifth 1155 and sixth 1165 emissive units may also be interchanged.

FIG. 14a shows a stacked light emitting device 1400 having two emissive units. The light emitting device 1400 may comprise one or more OLED, QLED, PeLED or I-LED emissive units or a combination thereof. Device 1400 may include a first electrode 970, a first emissive unit 1115, a charge generation layer 1140, a second emissive unit 1125, and a second electrode 980. The first electrode 970 may be directly connected to an external electrical source E1. The second electrode 980 may be directly connected to an external electrical source E2. The charge generation layer 1140 may be directly connected to an external electrical source E3. The charge generation layer 1140 may also be referred to as a middle electrode. Device 1400 may be fabricated by depositing the layers described in order. This architecture is simple and minimizes the number of layers in the device, which is beneficial for manufacturing.

The first emissive unit 1115 may be independently addressed by putting E1 on a positive potential with respect to E3 for a standard device architecture, or by putting E1 on a negative potential with respect to E3 for an inverted device architecture. The second emissive unit 1125 may be independently addressed by putting E3 on a positive potential with respect to E2 for a standard device architecture, or by putting E3 on a negative potential with respect to E2 for an inverted device architecture.

FIG. 14b shows a stacked light emitting device 1410 having two emissive units. The light emitting device 1410 may comprise one or more OLED, QLED, PeLED or I-LED emissive units or a combination thereof. Device 1410 may include a first electrode 970, a first emissive unit 1115, a charge generation layer 1140, a second emissive unit 1125, and a second electrode 980. The first electrode 970 may be directly connected to an external electrical source E1. The second electrode 980 may be directly connected to an external electrical source E2. The charge generation layer 1140 may comprise an electrically insulating layer 1150, depicted by the dashed line, that may electrically isolate the upper and lower regions of the charge generation layer 1140, and may be directly connected to two external electrical sources E3 and E4. The charge generation layer 1140 may also be referred to as a middle electrode. The lower region of charge generation layer 1140 may also comprise an upper electrode for the first emissive unit 1115. The upper region of the charge generation layer 1140 may also comprise a lower electrode for the second emissive unit 1125. The lower region of the charge generation layer 1140 may be addressed by E3 and the upper region of the change generation layer 1140 may be addressed by E4. Device 1410 may be fabricated by depositing the layers described in order. This architecture may be beneficial because it may enable the first emissive unit 620 and the second emissive unit 640 to be more easily selected and independently addressed.

The first emissive unit 1115 may be independently addressed by putting E1 on a positive potential with respect to E3 for a standard device architecture, or by putting E1 on a negative potential with respect to E3 for an inverted device architecture. The second emissive unit 1125 may be independently addressed by putting E4 on a positive potential with respect to E2 for a standard device architecture, or by putting E4 on a negative potential with respect to E2 for an inverted device architecture.

In one embodiment, all of the first 915 or 1115, second 925 or 1125, third 935 or 1135, fourth 945 or 1145, fifth 955 or 1155 and sixth 965 or 1165 regions have the same surface area. Pixel arrangements 800 in FIGS. 8 and 1000 in FIG. 10 depict such pixel arrangements. Such a pixel arrangement may be of advantage in that the manufacturing process may be simplified by each of the sub-pixels having the same surface area.

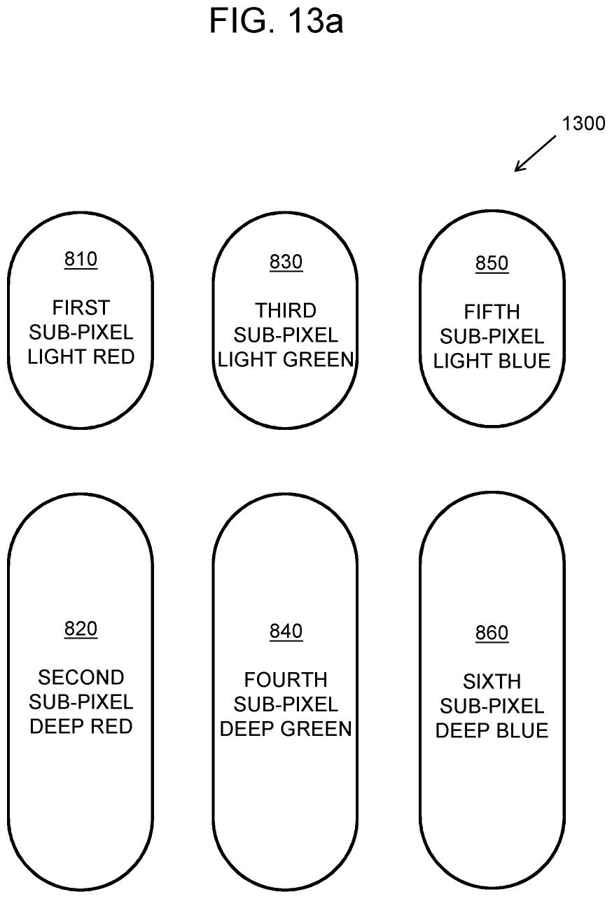

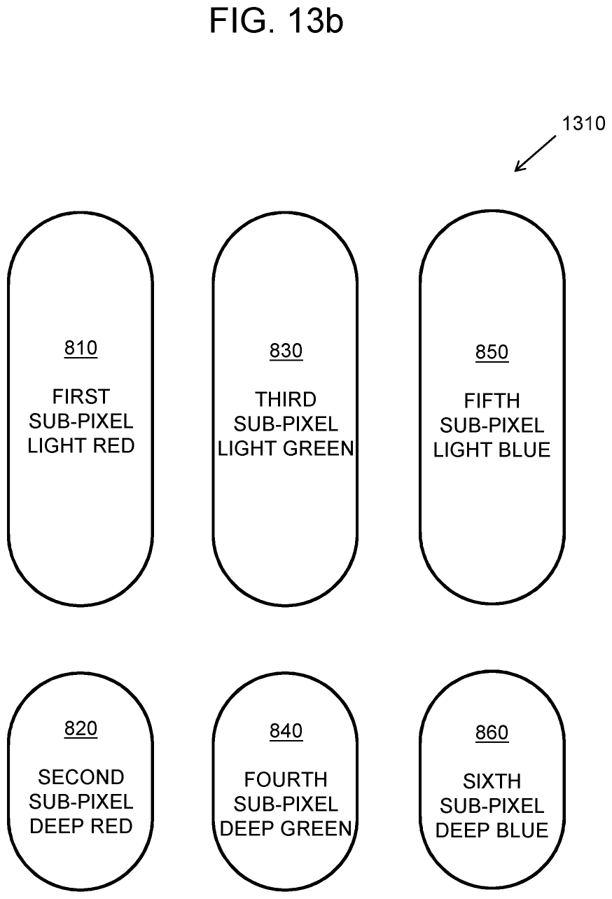

In one embodiment, at least one of the first 915 or 1115, second 925 or 1125, third 935 or 1135, fourth 945 or 1145, fifth 955 or 1155 and sixth 965 or 1165 regions has a surface area different from another of the first 915 or 1115, second 925 or 1125, third 935 or 1135, fourth 945 or 1145, fifth 955 or 1155 and sixth 965 or 1165 regions. Pixel arrangements 1300 in FIG. 13a and 1310 in FIG. 13b depict exemplary embodiments of such pixel arrangements. Pixel arrangement 1300 comprises light red 810, light green 830 and light blue 850 sub-pixels with smaller surface area than deep red 820, deep green 840 and deep blue 860 sub-pixels. Pixel arrangement 1310 comprises light red 810, light green 830 and light blue 850 sub-pixels with greater surface area than deep red 820, deep green 840 and deep blue 860 sub-pixels. FIG. 13a and 13b depict sub-pixels of different dimensions. However, it is also envisaged that emissive units may be of different dimensions. Optionally, regions of the same hue but different chromaticity may have different surface areas. Optionally, regions of different hues may have different surface areas.

Such pixel arrangements may be of advantage because they may reduce the power consumption and/or extend the operational lifetime of a display into which they are incorporated. One reason for this may be that some regions may have shorter operational lifetime than other regions. By increasing the surface area of such regions, it may be possible to generate the same total light output from the region at a lower brightness. For example, if the surface area of the region is increased by a factor of two, the brightness may be reduced by a factor of two, and the same total light output may still be achieved. It is well understood that by reducing brightness, operation lifetime for LEDs may be extended. Therefore, by increasing the surface area of regions that comprise LEDs with relatively shorter lifetime, the operational lifetime of the display regions may be more evenly balanced, and the operational lifetime of a display into which such a pixel arrangement is incorporated may be extended.

Optionally, the pixel arrangement may comprise one or more additional regions that have the same hue as one or more of the first 915 or 1115, second 925 or 1125, third 935 or 1135, fourth 945 or 1145, fifth 955 or 1155 and sixth 965 or 1165 regions. This may extend the total surface area of regions with relatively shorter lifetime, and the operational lifetime of a display into which such a pixel arrangement is incorporated may be extended. Optionally, such a pixel arrangement may comprise multiple light blue regions or multiple light green regions or multiple light red regions to respectively extend the lifetime of the light blue, light green and light red light emitting materials in the display. Optionally, such a pixel arrangement may comprise multiple deep blue regions or multiple deep green regions or multiple deep red regions to respectively extend the lifetime of the deep blue, deep green and deep red light emitting materials in the display.

In one embodiment, a consumer product may comprise a display as presented herein. Optionally, the display may be used in televisions, computer monitors, tablets, laptop computers, smart phones, cell phones, digital cameras, video recorders, smartwatches, fitness trackers, personal digital assistants, vehicle displays and other electronic devices. Optionally, the display may be used for micro-displays or heads-up displays for applications such as AR or VR. Optionally, the display may be used in light sources for interior or exterior illumination and/or signaling, in smart packaging or billboards.

A person skilled in the art will understand that only a few examples of use are described, but that they are in no way limiting.

Modifications to embodiments of the invention described in the foregoing are possible without departing from the scope of the invention as defined by the accompanying claims. Expressions such as “including”, “comprising”, “incorporating”, “consisting of”, “have”, “is” used to describe and claim the present invention are intended to be construed in a non-exclusive manner, namely allowing for items, components or elements not explicitly described also to be present. Reference to the singular is also to be construed to relate to the plural. Any numerals included within parentheses in the accompanying claims are intended to assist understanding of the claims and should not be construed in any way to limit subject matter claimed by these claims.

### PATENT REFERENCES

EP 0423283 B1, Friend et al., Electroluminescent Devices
U.S. Pat. No. 6,303,238 B1, Thompson et al., OLEDs Doped with Phosphorescent Compounds U.S. Pat. No. 7,279,704 B2, Walters et al., Complexes with Tridentate Ligands
U.S. Pat. No. 9,559,151 B2, Hack et al., OLED Display Architecture
US20220052262 A1, Levermore, Method of Manufacturing Perovskite Light Emitting Device by Inkjet Printing
EP 21740183.5, Levermore, Novel Light Emitting Device Architectures
U.S. Pat. No. 7,982,385 B2, Kimura et al., Display Device with a Plurality of Picture Elements and Electronic Device with Display Device
WO 2022/003352 A1, Levermore, Novel Light Emitting Device Architectures

### OTHER REFERENCES

S. Adjokatse et al., Broadly tunable metal halide perovskites for solid-state light-emission applications, Materials Today, Vol. 20, Issue 8, Pages 413-424 (2017).
Cheng et al., Hyperfluorescence™: Excel the performance, create the future, Journal of the Society for Information Display, Vol. 30, Issue 6, Pages 514-522 (2021).
Fukagawa et al., High-efficiency ultrapure green organic light-emitting diodes, Materials Chemistry Frontiers, Vol. 2, Pages 704-709 (2018).
Hosoumi et al., Ultra-wide Color Gamut OLED Display using a Deep-Green Phosphorescent Device with High Efficiency, Long Life, Thermal Stability, and Absolute BT.2020 Green Chromaticity, SID Symposium Digest of Technical Papers 2017, Vol. 48, Pages 13-16 (2017).
Jang et al., High Efficiency Green Phosphorescent Organic Light Emitting Diodes with Emission Structure of (TCTA/TCTA_{0.5}TPBi_{0.5}/TPBi):(pq)₂Ir(acac), Molecular Crystals and Liquid Crystals, Vol. 513, Pages 268-276 (2019).
Kathirgamanathan et al., Electroluminescent Organic and Quantum Dot LEDs: The State of the Art, Journal of Display Technology, Vol. 11, Number 5, Pages 480-493 (2015).
Soneira et al., iPhone 14 Pro Max Colour Gamuts: https://www.displaymate.com/Gamut 81P.html [accessed April 2023]
Takita et al., Highly efficient deep-blue fluorescent dopant for achieving low-power OLED display satisfying BT.2020 chromaticity, Journal of the SID 2018 (2018).
Uoyama et al., Highly efficient organic light-emitting diodes from delayed fluorescence, Nature, Vol. 492, Pages 234-238 (2012).
Weaver et al., Advances in Blue Phosphorescent Organic Light-Emitting Devices, SID Symposium Digest of Technical Papers 2006, Vol. 37, Issue 1, Pages 127-130 (2006).
Yu et al., Effect of the greenish-yellow emission on the color rendering index of white organic light-emitting devices, Organic Electronics, 15, Pages 2817-2821 (2014).

The invention claimed is:

1. A display comprising an arrangement of pixels, each pixel comprising:
a first region configured to emit red light of a first chromaticity having first CIE 1931 (x, y) chromaticity coordinates of (x1, y1);
a second region configured to emit red light of a second chromaticity having second CIE 1931 (x, y) chromaticity coordinates of (x2, y2);
a third region configured to emit green light of a third chromaticity having third CIE 1931 (x, y) chromaticity coordinates of (x3, y3);
a fourth region configured to emit green light of a fourth chromaticity having fourth CIE 1931 (x, y) chromaticity coordinates of (x4, y4);
a fifth region configured to emit blue light of a fifth chromaticity having fifth CIE 1931 (x, y) chromaticity coordinates of (x5, y5);
and a sixth region configured to emit blue light of a sixth chromaticity having sixth CIE 1931 (x, y) chromaticity coordinates of (x6, y6); wherein
the second chromaticity is different to the first chromaticity;
the fourth chromaticity is different to the third chromaticity; and
the sixth chromaticity is different to the fifth chromaticity; wherein
the first, third and fifth chromaticities define the primary colours of a first colour gamut;
the second, fourth and sixth chromaticities define the primary colours of a second colour gamut;
the area of the first colour gamut is less than 55% of the area of the second colour gamut in the CIE 1931 (x, y) chromaticity diagram;
the first colour gamut and the second colour gamut both enclose the D65 white point; and
the fifth region emits blue light with CIE 1931 x coordinate x5 in the range of 0.075 to 0.155 and CIE 1931 y coordinate y5 in the range of 0.081 to 0.245.

2. The display of claim 1, wherein
the area of the first colour gamut is less than 45% of the area of the second colour gamut in the CIE 1931 (x, y) chromaticity diagram.

3. The display of claim 1, wherein
the area of the first colour gamut is less than 35% of the area of the second colour gamut in the CIE 1931 (x, y) chromaticity diagram.

4. The display of any one of claims 1 to 3, wherein
the second chromaticity coordinates (x2, y2) are not contained within a one-step MacAdam ellipse that is centralized on the first chromaticity coordinates (x1, y1);
the fourth chromaticity coordinates (x4, y4) are not contained within a one-step MacAdam ellipse that is centralized on the third chromaticity coordinates (x3, y3); and
the sixth chromaticity coordinates (x6, y6) are not contained within a one-step MacAdam ellipse that is centralized on the fifth chromaticity coordinates (x5, y5).

5. The display of any one of claims 1 to 3, wherein
the second chromaticity coordinates (x2, y2) are not contained within a three-step MacAdam ellipse that is centralized on the first chromaticity coordinates (x1, y1);
the fourth chromaticity coordinates (x4, y4) are not contained within a three-step MacAdam ellipse that is centralized on the third chromaticity coordinates (x3, y3); and
the sixth chromaticity coordinates (x6, y6) are not contained within a three-step MacAdam ellipse that is centralized on the fifth chromaticity coordinates (x5, y5).

6. The display of any one of claims 1 to 5, wherein
the first region emits light having a first peak wavelength;
the second region emits light having a second peak wavelength;
the third region emits light having a third peak wavelength;
the fourth region emits light having a fourth peak wavelength;
the fifth region emits light having a fifth peak wavelength; and
the sixth region emits light having a sixth peak wavelength; wherein
the second peak wavelength is at least 4 nm greater the first peak wavelength;
the fourth peak wavelength is at least 4 nm less than the third peak wavelength; and
the sixth peak wavelength is at least 4 nm less than the fifth peak wavelength.

7. The display of any one of claims 1 to 6, wherein
the first CIE 1931 (x, y) chromaticity coordinates (x1, y1) may be converted to first CIE 1976 (u′, v′) chromaticity coordinates (u1, v1);
the second CIE 1931 (x, y) chromaticity coordinates (x2, y2) may be converted to second CIE 1976 (u′, v′) chromaticity coordinates (u2, v2);
the third CIE 1931 (x, y) chromaticity coordinates (x3, y3) may be converted to third CIE 1976 (u′, v′) chromaticity coordinates (u3, v3);
the fourth CIE 1931 (x, y) chromaticity coordinates (x4, y4) may be converted to fourth CIE 1976 (u′, v′) chromaticity coordinates (u4, v4);
the fifth CIE 1931 (x, y) chromaticity coordinates (x5, y5) may be converted to fifth CIE 1976 (u′, v′) chromaticity coordinates (u5, v5); and
the sixth CIE 1931 (x, y) chromaticity coordinates (x6, y6) may be converted to sixth CIE 1976 (u′, v′) chromaticity coordinates (u6, v6); wherein
the first chromaticity coordinates (u1, v1) and the second chromaticity coordinates (u2, v2) are sufficiently different such that the difference in chromaticity as defined by Δuv is 0.010 or more;
the third chromaticity coordinates (u3, v3) and the fourth chromaticity coordinates (u4, v4) are sufficiently different such that the difference in chromaticity as defined by Δuv is 0.010 or more; and
the fifth chromaticity coordinates (u5, v5) and the sixth chromaticity coordinates (u6, v6) are sufficiently different such that the difference in chromaticity as defined by Δuv is 0.010 or more.

8. The display of any one of claims 1 to 7, wherein
the first (u1, v1), third (u3, v3) and fifth (u5, v5) chromaticities define the primary colours of the first colour gamut;
the second (u2, v2), fourth (u4, v4) and sixth (u6, v6) chromaticities define the primary colours of the second colour gamut; and:
the area of the first colour gamut is less than 50% of the area of the second colour gamut in the CIE 1976 (u′, v′) chromaticity diagram.

9. The display of claim 8, wherein
the area of the first colour gamut is less than 40% of the area of the second colour gamut in the CIE 1976 (u′, v′) diagram.

10. The display of claim 8, wherein
the area of the first colour gamut is less than 25% of the area of the second colour gamut in the CIE 1976 (u′, v′) diagram.

11. The display of any one of claims 1 to 10, wherein
the first region and the second region both emit red light with peak wavelength in the range of 580 nm to 780 nm;
the third region and the fourth region both emit green light with peak wavelength in the range of 500 nm to 580 nm; and
the fifth region and the sixth region both emit blue light with peak wavelength in the range of 380 nm to 500 nm.

12. The display of any one of claims 1 to 11, wherein
the first region emits lighter red light, and the second region emits deeper red light;
the third region emits lighter green light, and the fourth region emits deeper green light; and
the fifth region emits lighter blue light, and the sixth region emits deeper blue light.

13. The display of any one of claims 1 to 12, wherein
the first region emits red light with a peak wavelength in the range of 580 nm to 610 nm and the second region emits red light with a peak wavelength in the range of 610 nm to 780 nm;
the third region emits green light with a peak wavelength in the range of 540 nm to 580 nm and the fourth region emits green light with a peak wavelength in the range of 500 nm to 540 nm; and
the fifth region emits blue light with a peak wavelength in the range of 470 nm to 500 nm and the sixth region emits blue light with a peak wavelength in the range of 380 nm to 470 nm.

14. The display of any one of claims 1 to 13, wherein
the third region emits green light with a peak wavelength in the range of 550 nm to 560 nm.

15. The display of claim 14, wherein
the third region emits green light with a peak wavelength in the range of 555 nm to 557 nm.

16. The display of any one of claims 1 to 15, wherein
the first region emits red light with a peak wavelength in the range of 580 nm to 600 nm;
the third region emits green light with a peak wavelength in the range of 550 nm to 560 nm; and
the fifth region emits blue light with a peak wavelength in the range of 465 nm to 485 nm.

17. The display of claim 16, wherein
the first region emits red light with a peak wavelength in the range of 585 nm to 595 nm;
the third region emits green light with a peak wavelength in the range of 550 nm to 560 nm; and
the fifth region emits blue light with a peak wavelength in the range of 470 nm to 480 nm.

18. The display of any one of claims 1 to 17, wherein
the first region emits red light with a CIE 1931 x coordinate of less than 0.640 and the second region emits red light with a CIE 1931 x coordinate of 0.640 or more;
the third region emits green light with a CIE 1931 y coordinate of less than 0.650 and the fourth region emits green light with a CIE 1931 y coordinate of 0.650 or more; and
the fifth region emits blue light with a CIE 1931 y coordinate of more than 0.080 and the sixth region emits blue light with a CIE 1931 y coordinate of 0.080 or less.

19. The display of claim 18, wherein
the first region emits red light with CIE 1931 x coordinate in the range of 0.500 to 0.575 and CIE 1931 y coordinate in the range of 0.425 to 0.500;
the third region emits green light with CIE 1931 x coordinate in the range of 0.335 to 0.415 and CIE 1931 y coordinate in the range of 0.575 to 0.649; and
the fifth region emits blue light with CIE 1931 x coordinate in the range of 0.075 to 0.155 and CIE 1931 y coordinate in the range of 0.081 to 0.245.

20. The display of claim 18, wherein
the first region emits red light with CIE 1931 x coordinate in the range of 0.515 to 0.560 and CIE 1931 y coordinate in the range of 0.440 to 0.485;
the third region emits green light with CIE 1931 x coordinate in the range of 0.355 to 0.395 and CIE 1931 y coordinate in the range of 0.595 to 0.635; and
the fifth region emits blue light with CIE 1931 x coordinate in the range of 0.100 to 0.140 and CIE 1931 y coordinate in the range of 0.110 to 0.150.

21. The display of any one of claims 1 to 20, wherein
the second colour gamut is the DCI-P3 colour gamut.

22. The display of any one of claims 1 to 20, wherein
the second colour gamut is the Rec. 2020 colour gamut.

23. The display of any one of claims 1 to 22, wherein all of the first, second, third, fourth, fifth and sixth regions comprise organic LEDs (OLEDs).

24. The display of any one of claims 1 to 22, wherein all of the first, second, third, fourth, fifth and sixth regions comprise inorganic LEDs (I-LEDs).

25. The display of any one of claims 1 to 22, wherein all of the first, second, third, fourth, fifth and sixth regions comprise quantum dot LEDs (QLEDs) or perovskite LEDs (PeLEDs)

26. The display of any one of claims 1 to 25, wherein all of the first, second, third, fourth, fifth and sixth regions comprise MiniLEDs, MicroLEDs or NanoLEDs.

27. The display of any one of claims 1 to 26, wherein all of the first, second, third, fourth, fifth and sixth regions have the same surface area.

28. The display of any one of claims 1 to 26, wherein at least one of the first, second, third, fourth, fifth and sixth regions has a surface area different from another of the first, second, third, fourth, fifth and sixth regions.

29. The display of any one of claims 1 to 28, wherein
the first region comprises a first sub-pixel that comprises a first LED that is configured to emit red light of the first chromaticity;
the second region comprises a second sub-pixel that comprises a second LED that is configured to emit red light of the second chromaticity;
the third region comprises a third sub-pixel that comprises a third LED that is configured to emit green light of the third chromaticity;
the fourth region comprises a fourth sub-pixel that comprises a fourth LED that is configured to emit green light of the fourth chromaticity;
the fifth region comprises a fifth sub-pixel that comprises a fifth LED that is configured to emit blue light of the fifth chromaticity; and
the sixth region comprises a sixth sub-pixel that comprises a sixth LED that is configured to emit blue light of the sixth chromaticity; wherein
each of the first, second, third, fourth, fifth and sixth LEDs comprise:
a first electrode;
a second electrode; and
an emissive layer; wherein
the emissive layer is disposed over the first electrode;
the second electrode is disposed over the emissive layer; and
none of the first, second, third, fourth, fifth or sixth LEDs are disposed over each other.

30. The display of any one of claims 1 to 28, wherein
the first region comprises a first emissive unit that is configured to emit red light of the first chromaticity;
the second region comprises a second emissive unit that is configured to emit red light of the second chromaticity;
the third region comprises a third emissive unit that is configured to emit green light of the third chromaticity;
the fourth region comprises a fourth emissive unit that is configured to emit green light of the fourth chromaticity;
the fifth region comprises a fifth emissive unit that is configured to emit blue light of the fifth chromaticity; and
the sixth region comprises a sixth emissive unit that is configured to emit blue light of the sixth chromaticity; wherein
a first sub-pixel comprises a first stacked LED comprising the first and second emissive units;
a second sub-pixel comprises a second stacked LED comprising the third and fourth emissive units; and
a third sub-pixel comprises a third stacked LED comprising the fifth and sixth emissive units; wherein
the first stacked LED comprises:
a first electrode;
a second electrode;
the first emissive unit comprising a first emissive layer;
the second emissive unit comprising a second emissive layer; and
a charge generation layer; wherein
the first emissive unit, the second emissive unit and the charge generation layer are all disposed between the first electrode and the second electrode;
the first emissive unit is disposed over the second emissive unit, or vice versa;
the first emissive unit and the second emissive unit are separated by the charge generation layer; and
the first emissive unit and the second emissive unit are independently addressed and may emit light independently of each other;
the second stacked LED comprises:
a first electrode;
a second electrode;
the third emissive unit comprising a third emissive layer;
the fourth emissive unit comprising a fourth emissive layer; and
a charge generation layer; wherein
the third emissive unit, the fourth emissive unit and the charge generation layer are all disposed between the first electrode and the second electrode;
the third emissive unit is disposed over the fourth emissive unit, or vice versa;
the third emissive unit and the fourth emissive unit are separated by the charge generation layer; and
the third emissive unit and the fourth emissive unit are independently addressed and may emit light independently of each other; and
a third stacked LED comprises:
a first electrode;
a second electrode;
the fifth emissive unit comprising a fifth emissive layer;
the sixth emissive unit comprising a sixth emissive layer; and
a charge generation layer; wherein
the fifth emissive unit, the sixth emissive unit and the charge generation layer are all disposed between the first electrode and the second electrode;
the fifth emissive unit is disposed over the sixth emissive unit, or vice versa;
the fifth emissive unit and the sixth emissive unit are separated by the charge generation layer; and
the fifth emissive unit and the sixth emissive unit are independently addressed and may emit light independently of each other.

31. A consumer product comprising the display of any one of claims 1 to 30.
